(19) United States
(12) Patent Application Publication
(10) Pub. No.: US 2024/0388309 A1
(43) Pub. Date: Nov. 21, 2024

(54) Binary Data Compression / Decompression Method

(71) Applicant: Radu Mircea Secareanu, Phoenix, AZ (US)

(72) Inventor: Radu Mircea Secareanu, Phoenix, AZ (US)

(21) Appl. No.: 18/777,236

(22) Filed: Jul. 18, 2024

Related U.S. Application Data
(63) Continuation-in-part of application No. 17/974,057, filed on Oct. 26, 2022, now Pat. No. 12,095,485.

(51) Int. Cl. H03M 7/30

(52) U.S. Cl. CPC H03M 7/6011; H03M 7/3064

(57) ABSTRACT

A binary data compression/decompression method is disclosed, where any input binary data string (IFDS) is uniquely and reversibly compressed/decompressed without any data loss by first uniquely formatting and fully describing the IFDS using a set of binary constructs, followed by creating complex structures from custom combinations of the binary constructs that occur within the IFDS content, wherein the choice of the custom combinations depend on the IFDS content therefore creating IFDS content variations and distributions from an expected nominal base reflecting the actual content of the IFDS, followed by uniquely processing these variations and distributions using several schemes, each bringing a unique compression feature, and wherein once this processing completes, another repeating compression cycle can be applied until the desired compressed file size or a file floor size limit is reached, size below which the disclosed compression has limitations.

### CROSS-REFERENCE TO RELATED APPLICATIONS

Application is a Continuation-in-Part (CIP) Application, claiming benefit of the following non-provisional (parent) application:
application number: Ser. No. 17/974,057
Applicant Name: Radu Mircea Secareanu
Filing date: 26 Oct. 2022

Full specification and drawings of the parent application are included, with the new matter added for CIP following in every section of the disclosure.

### FIELD

The present disclosure relates to binary data compression/decompression methods, and in particular to binary data compression/decompression methods that are suitable to be implemented in silicon, as a circuit, in addition (or not only) to be implementable in software.

### BACKGROUND

Certain aspects disclosed in the utility patent applications (UPA) mentioned below are being used in the present disclosure. These UPA are filed by the same unique inventor as the present disclosure. These UPA are mentioned here as background for this disclosure. The present disclosure represents new matter. These background utility patent applications (UPA) are:
application number: Ser. No. 17/398,728
Applicant Name: Radu Mircea Secareanu
Filing date: 10 Aug. 2021
Application Number: Ser. No. 17/573,438.
Applicant Name: Radu Mircea Secareanu
Filing date: 11 Jan. 2022
Application Number: Ser. No. 17/667,650
Applicant Name: Radu Mircea Secareanu
Filing date: 9 Feb. 2022

### SUMMARY

At the onset, a note regarding the structure of this disclosure is required, note that will enable better understanding of the flow of the disclosure. Key concepts are defined, detailed, and exemplified, concepts that the disclosed embodiments from the present disclosure are based on. The binary data compression/decompression method, or the BDCD method, is progressively introduced during this process.

In summary, the BDCD method works as follows: an Initial Full Data String (IFDS) is serially formatted into a number of sequential Processing Strings (PS), where the length of each PS is determined by two conditions: 1) the occurrence of a fixed bit pattern, called Delimiter (DE) or 2) by the reach of a set maximum limit number of bits and/or a group of bits of well defined content with a number of bits less than the said maximum limit number of bits. Every PS consists of two parts: a root identifier (RI) part, followed by a detail (DL) part. A well defined set of RI is formed, and with this set, any arbitrary IFDS can be described. This description of any arbitrary IFDS using this well defined set of RI is called internal formatting (INFORM) of the IFDS. All these details are described and related claims are formulated in the above mentioned UPA. The BDCD method is processing the arbitrary RI content of an arbitrary IFDS to obtain data compression. The BDCD method is achieving this data compression by creating complex structures from combining RI, therefore creating IFDS content variations and distributions from the nominal IFDS content, variations and distributions that reflect the actual content of the arbitrary IFDS. The BDCD method is processing these complex structures using several schemes, as detailed in this disclosure. Once this processing completes (i.e. the end of the arbitrary IFDS is reached), it is called that the end of one compression cycle is reached. Another compression cycle can be applied to the data by repeating the process, using as new IFDS the output of the just completed compression cycle. Every new BDCD method cycle consists of the INFORM step of the previously completed compression output, followed by the above mentioned compression processing. Theoretically, an unlimited number of cycles can be employed. Practically, there is a file floor size limit (i.e. a file that is smaller than the file floor size may not provide compression gain). The file floor size limit depends on the BDCD method implementation options, and will be exemplified in the disclosure.

The decompression is perfectly mirrored to the compression process, leading to an identical, lossless restored file to the initial IFDS, which was the input to the first cycle.

The preferred implementation of the BDCD method is a hardware implementation. A software implementation will replicate identically all the functionality of the BDCD method, therefore the hardware and the software implementations are perfectly equivalent from the functionality point of view. A hardware implementation is more expensive than a software implementation, but it is faster in term of compression/decompression speed. Therefore, there is a trade-off between cost and speed between a hardware and software implementation. Because a hardware implementation is faster than a software implementation, certain applications are preferable to be implemented, and possibly only enabled, in a hardware implementation. On the other hand, because a software implementation has a much lower cost than a hardware implementation, certain applications are preferably implemented in a software implementation enabling a low cost for the user.

Concerning the hardware implementation aspects, as will be apparent from the details presented in this disclosure to a person familiar with digital design, the preferred hardware implementation of the BDCD method is, due to the serial nature of the BDCD method, a fully-pipelined based architecture. Such an architecture will provide the highest compression/decompression speed possible in a hardware implementation.

The new matter introduced by the CIP application is summarized as follows. Four compression schemes are introduced in the parent application. In summary, all these four schemes generate compression by creating, identifying, and processing content variations and distributions found in the nominal content of a said arbitrary IFDS in term of said uniquely developed set of RI. The new matter introduced by the CIP forces the identification of content variations and distributions of unique properties in said IFDS that lead to efficient compression for each of the four compression schemes from the parent application. Hardware implementation details are highlighted.

### BRIEF DESCRIPTION OF DRAWINGS

Embodiments will be described, by way of example, with reference to the drawings, in which

FIG. 1 is used to summarise the set of Root Identifiers (RI), set that is used to describe any arbitrary binary input string, set that is used in one or more of the embodiments.

FIG. 2 is used to summarise the key embodiments and steps of the disclosed Scheme 1.

FIG. 3 is used to summarise the key embodiments and steps of the disclosed Scheme 2.

FIG. 4 is used to summarise the key embodiments and steps of the disclosed Scheme 3.

FIG. 5 is used to summarise the key embodiments and steps of the disclosed Scheme 4.

FIG. 6 is used to summarise the data flow from the initial data input to the final compressed data output, in accordance to one or more of the disclosed embodiments.

FIG. 7 is used to summarise a first procedure to force identification of content variations and distributions of unique properties in said IFDS, as used in one or more of the embodiments.

FIG. 8 is used to summarise a second procedure to force identification of content variations and distributions of unique properties in said IFDS, as used in one or more of the embodiments.

FIG. 9 is used to summarise the implementation blocks, as used in one or more of the embodiments.

### DETAILED DESCRIPTION OF THE INVENTION

At the outset it should be noted that the examples presented in the disclosure are in no way limiting, and the skilled person will appreciate that the disclosure is equally applicable to multiple variations and alternatives, and multiple optimizations are possible to increase the performance, such as the compression efficiency and speed.

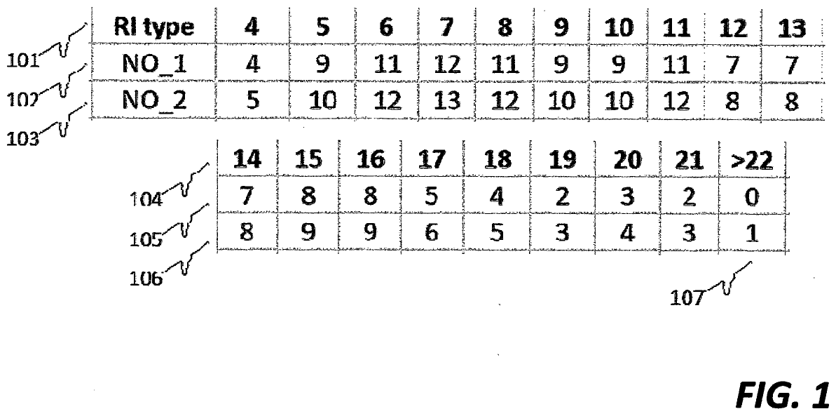

As disclosed in the above mentioned UPA, in particular in Ser. No. 17/667,650, any arbitrary IFDS can be described using a well defined set of PS, respectively a well defined set of RI. This set of RI is summarised in FIG. 1, where:
Rows 101 and 104 detail existing RI classes. The RI classes are greater than 3, where the number represents the number of bits in the RI.
Rows 102 and 105 detail the number of distinct RI in each class, called RI class members, excluding RI corresponding to PS of same type bits.
Rows 103 and 106 detail the number of distinct RI in each class, called RI class members, including RI corresponding to PS of same type bits.
Column 107, labelled “>22” (greater than 22), is placed in FIG. 1 for convenience, detailing in reality all PS of same type bits greater than 22. In reality, there is one entry/column for every PS of same type bits such as 22, 23, 24 . . . , theoretically to infinity, where each entry has one member. There are no RI greater than 22 other than RI describing same type bits PS.

Each RI class member has a very well defined nominal probability of occurrence in an IFDS. A member of class 4 RI has a nominal probability of occurrence of 6.25%, and this probability halves with every class increase. A 6.25% probability means for example that one in 16 PS (RI) that occurs in an arbitrary IFDS, is of that member type. This is a nominal occurrence rate, wherein in reality, there is a variability and distribution of occurrences for every member of every RI class. The goal of the BDCD method is to exploit this variability and distribution in order to create compression for any arbitrary IFDS. To achieve this goal, constructs of RI content of an IFDS are created and processed using various schemes. These constructs can cover RI grouping, such as pairs, triplets, quadruplets, etc. of RI. In this disclosure, exemplification will be given using pairs of RI. For higher order grouping, the compression behaviour improves, with the disadvantage that a higher order grouping will require a larger IFDS slice, therefore a larger file floor size, as introduced above. Many other constructs of the RI content of an IFDS, other than grouping, are possible-such other constructs are not detailed in this disclosure because the concepts and outcome are similar.

Since, as shown in FIG. 1, an RI can have minimum 4 bits and maximum infinity, a pair of RI can therefore have minimum 8 bits and maximum infinity. A specific RI pair of X number of bits will be called in this disclosure a member of RI pair class X. For example, since there are 5 members of class 4 RI, there will be 25 members of RI pair class 8. Since there are 5 members of class 4 RI and 10 members of class 5 RI, there will be 100 members of RI pair class 9, representing all combinations of (a class 4 RI member) followed by (a class 5 RI member), or (a class 5 RI member) followed by (a class 4 RI member), in short, 4-5 or 5-4. Similarly, RI pair class 10 will have 220 members, representing all possible combinations 4-6, 5-5, 6-4. The maximum number of members in an RI pair class is for RI pair class 22, with 1276 members.

The concepts of “contained class”, “origin class”, and “target class” are introduced. A contained class is where all compression process occurs within that class only. An origin class and a target class create a pair of classes to complete the compression process. The compression within a contained class is different than the compression within a pair of origin class and a target class, both these compression processes being described below.

The concept of “pairing range” is introduced. A pairing range represents a set of PS within a processing string in which a pair of two RI can be created. Conventionally, a pair of two RI is created between two consecutive RI (PS). A pairing range can be for example a set of 32 RI (PS), where a pair of RI can be created between any two members of the set. There are 2*C32_2 (twice times combinations of 32 taken 2) pairs that can be considered in this set of 32 RI, i.e. 992 pairs. Note that in this 992 pairs there are direct and reverse pairs—for example, in the 32 RI set, the pair created between RI number 9 and RI number 15 (pair 9-15) is a direct pair, while the pair created between RI number 15 and RI number 9 (pair 15-9) is a reverse pair. If RI number 9 is of class 4 and RI number 15 is of class 5, pair 9-15 will create a class 9 RI pair of configuration 4-5, while pair 15-9 will create a class 9 RI pair of configuration 5-4, where the two configurations are dependent of each other, being made of same class 4 and class 5 RI members, and having the same number of occurrences in a string and RI pairing range. Therefore, direct and reverse pairs are dependent on each other. In a pairing range therefore, there are a number of independent pairs and double that number of dependent pairs (in the 32 RI pairing range example, there are 496 independent pairs and 992 dependent pairs).

The size of a pairing range is a function of what RI pair class is used. The RI pair class, in turn, is chosen as a function of desired variability and distribution (the larger the RI pair class, the larger the variability and distribution, and therefore more beneficial for compression. For example, if RI pair class 9 is chosen, the size of pairing range is 32, and the variability and distribution is created over a matrix of 496 independent pairs by 100 members. If RI pair class 10 is chosen, the size of the pairing range is 64, and the variability and distribution is created over a matrix of 2016 independent pairs by 220 members. The size of the pairing range is chosen as the minimal size to contain one nominal occurrence member of the lowest probability of the respective RI pair class.

### BDCD_s1: BDCD Scheme 1

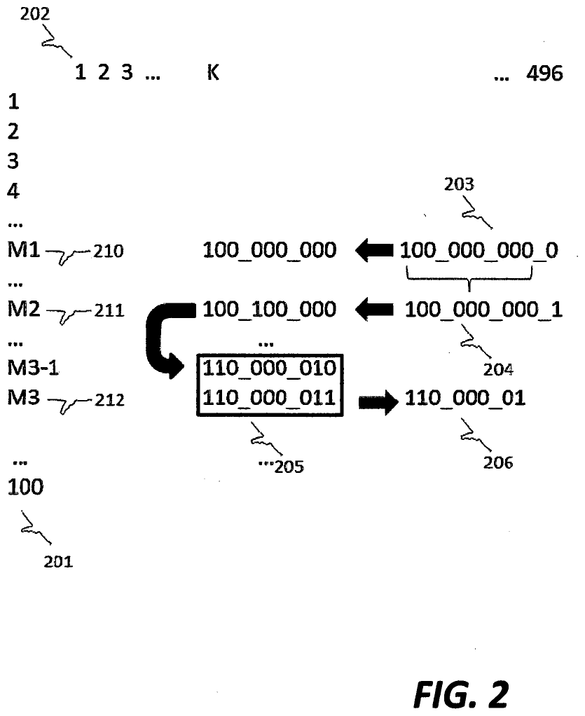

Scheme 1 refers to a BDCD implementation using a contained class. In the exposition for Scheme 1, reference will be made to FIG. 2. RI pair class 9 is used as the contained class, to exemplify. As outlined, the pairing range for class 9 is 32, and there are 496 distinct independent pairs that can be created. For each of the 100 members in the class, in one pairing range, nominally, there is 1 independent pair that occurs. For an ideal distribution, in approximately 512 pairing ranges (i.e. 512*32 PS, or about 16,000 PS), all 496 distinct independent pairs occur once for that member. An IFDS portion, or slice, is considered, where the size of this slice is a multiple of 16,000 PS, so that for each member, each of the 496 independent pairs is nominally represented by the same integer number of occurrences.

In an arbitrary IFDS, there is a distribution of occurrences for each of the 496 independent pairs per member, where a distribution matrix of occurrences of size 496 (the columns 202 in FIG. 2) by 100 (the rows 201 in FIG. 2) is created, distribution matrix that reflects the content of the arbitrary IFDS slice. Out of this matrix, of 49,600 entries, where each entry represents a member-pair construct, two entries, E1 (210 in FIG. 2) and E2 (211 in FIG. 2), that have the least occurrences (N1 respectively N2), and one entry E3 (212 in FIG. 2) that has the maximum occurrences (N3), are located. E1, E2, and E3 must belong to the same pair (same matrix column K in FIG. 2).

Say, within that pair (matrix column), E1 corresponds to member M1 and has the regular representation as 100_000_000 (9 bit representation), then this representation becomes 100_000_000_0 (10 bit representation 203 in FIG. 2). E2, corresponding to member M2 will be represented by 100_000_000_1 (204 in FIG. 2). The original representation of M2 (say this was 100_100_000) becomes available (not used). E3, corresponding to member M3, has representation 110_000_011. The member with the representation where the last bit from the M3 representation is flipped (i.e. 110_000_010, member (M3-1) in FIG. 2) will be represented by the original M2 representation, this transfer achieving the availability of 100_100_000 to 110_000_010. Once 110_000_010 becomes available, M3 can be represented using 8 bits (i.e. 110_000_01, 206 in FIG. 2), by combining the two representations in block 205 of FIG. 2. Therefore, each occurrence of members M1 and M2, with least occurrences, will be represented using 10 bits (at a loss of 1 bit per occurrence), while each occurrence of the said member with maximum occurrences (M3) will be represented using 8 bits (at a gain of 1 bit per occurrence). A net gain is obtained if N3>N1+N2.

Note that in the above exposition of the BDCD_s1, every pair is using an alternate representation of same number of bits as the original pair, alternate representation that can be created straightforward. The condition for this alternate representation is that all members within an RI pair class have the last bits as a consecutive counter. For example, RI pair class 9, class that has 100 members, will need a 7 bit counter, and the representation will be <two fixed bits>_<7 bit counter>. Obviously 28 positions of the 7 bit counter will become available and transferred into the 10 bit representation of RI pair class 10. This alternate representation of pairs is needed only for the matrix pair (column) that carry the E1, E2, E3 (M1, M2, M3).

BDCD_s1 does not require such alternate representation of RI pairs for implementation, but such alternate representation is recommended because the implementation is easier and more clear/focused. BDCD_s1 is disclosed when the implementation employs this alternate representation. BDCD_s2 implementation also recommends to have such an alternate representation of the RI pairs, however, for clarity in term of disclosing how to implement such a scheme without employing such an alternate representation, BDCD_s2 is disclosed without employing such an alternate representation. Both schemes can be implemented either way (with or without alternate representation), and since both implementations are disclosed, one per scheme, the disclosure is complete. The implementations are therefore not repeated in this disclosure both for each scheme.

Continuing with the BDCD_s1 disclosure, note that BDCD_s1 will require one pair (matrix column) out of 496 independent pairs to implement the scheme. Say this pair occurs between PS number 4 and PS number 27 in the 32 PS pairing range (i.e. matrix column 4_27) of every 32 PS pairing range. From the point of view of this 4_27 pair, the other 30 members of the 32 pairing range are irrelevant, they may remain unpaired, or may be paired in a certain way in order to achieve further compression for another of those pairs. A maximum of 16 pairs can be created and achieve compression for a 32 pairing range, so, a maximum of 16 out of the 496 matrix columns will be active for an IFDS slice. Within one of these 16 columns, there may be more than one E1-E2-E3 triplets that meet the condition for compression (i.e. N3>N1+N2).

To the condition for compression that the E1-E2-E3 triplets must meet, the cost must be added, where the cost represents the number of bits to specify the pair (matrix column, 9 bits required for class 9 that has 496 independent pairs) and the three M1-M2-M3 members (7 bits required for class 9 that has 100 members). Therefore, the cost for class 9 is 30 bits. The condition for compression becomes N3>N1+N2+30, or, generally, N3>N1+N2+cost.

### Examples

a. For an IFDS slice of 32*16,000 with a nominal N of 32, N1=18, N2=15, minimum N3=18+15+30. So, N1=18, N2=15, N3=63, N_nom=32
b. For an IFDS slice of 128*16,000 with a nominal N of 128, N1=70, N2=80, minimum N3=70+80+30. So, N1=70, N2-80, N3=180, N_nom=128
c. If there are two triplets on the same matrix column (pair) the pair (column) cost (9 bits) is shared between the two triplets, leading to a total cost per triplet of 25.5 (26) (instead of 30).
d. If the same triplet is used for all 16 pairs chosen in a suite of a pairing range used in an IFDS slice, then the cost per pair per triplet becomes 9+21/16, or 11 (instead of 30).
e. For an IFDS slice of 8*16,000 with a nominal N of 8, it is a high probability that within the 496*100 member distribution in the matrix, there are entries with zero occurrences. In this case, only the entry with zero occurrences suffice (instead of two members with minimal occurrence), i.e. E1 suffice instead of E1 and E2. The cost is also reduced from 30 to 23 (i.e. 9+2*7). In this case, N1=0, resulting in a minimum N3=0+23. So, N1=0, N3=23, N_nom=8.
f. Note at (e) above that the largest slice having an entry with zero occurrences is desired. For example, if the slice is 16*16,000, N1=0, N3=23, N_nom=16, distribution that relaxes the requirements for N3.
g. If the two E1 and E2 entries (with N1 and N2 occurrences) have the same RI members (such as 4-5 and 5-4, with the same class 4 and class 5 RI), then the cost is reduced from 30 to 23 (9 bit for the matrix column plus 7 bit for the 4-5 member plus 7 bit for E3 member). A 1 bit identifier for this option may be added to the cost, for a total cost of 24. This option is particularly useful for low N_nom slices (such as N1=16, N2=17, N3=57, for N_nom=32).
h. If multiple IFDS slices have similar entries, then the cost is divided to the number of slices. For example, for a cost of 30 and three slices that have same E1, E2, E3, the cost per slice becomes 10. An identifier plus a counter specifying the number of slices may be added to the cost, addition that is also divided to the number of slices, leading to the cost per slice increase of one bit (11 instead of 10).
i. If at (e) above, the E3 entry (with N3 occurrences) has the same RI members as the E1 entry (with zero occurrences) as described at (g) above, the cost is further reduced to 9 (for the matrix column) plus 7 (for the E1 entry) plus an identifier (1 bit) to specify this option. This option is particularly useful for low N_nom (for example, N1=0, N3=17 (cost, 9+7+1), N_nom=8).

Multiple variations are possible, Multiple such triplets and duplets can exist in an IFDS slice distribution within one matrix column and within the 16 pairings within the pairing range, to maximize the compression. In addition, multiple RI pair classes can be considered at the same time, such as class 9, class 10, and class 11. The larger the class, the wider the distribution of entries (for example, for class 10, the matrix size is 2016*220), therefore the larger the probability to find triplets that meet the compression condition or to find entries with zero occurrences. Note also that focusing the compression on implementing entries with zero occurrences will insure IFDS slices smaller in size, which is extremely beneficial for certain applications such as live HI-Fi audio broadcasting, including telephony.

### BDCD_s2: BDCD Scheme 2

Scheme 2 refers to a BDCD implementation using an origin class and a target class. Scheme 2 does not work in a contained class. Scheme 2 is disclosed in an implementation that does not employ the alternate representation of pairs. As mentioned, this is done for full disclosure, in order to exemplify how to implement such a scheme both ways (with or without employing alternate representation of pairs). As mentioned, both Scheme 1 and Scheme 2 can be implemented either way. Also as mentioned, while Scheme 2 is disclosed in an implementation that does not employ an alternate representation of pairs, employing such a representation is recommended because it is easier and has more clarity. However, qualifications such as “easier” and “more clarity”, are subjective; there is a complete freedom to implement one way or another.

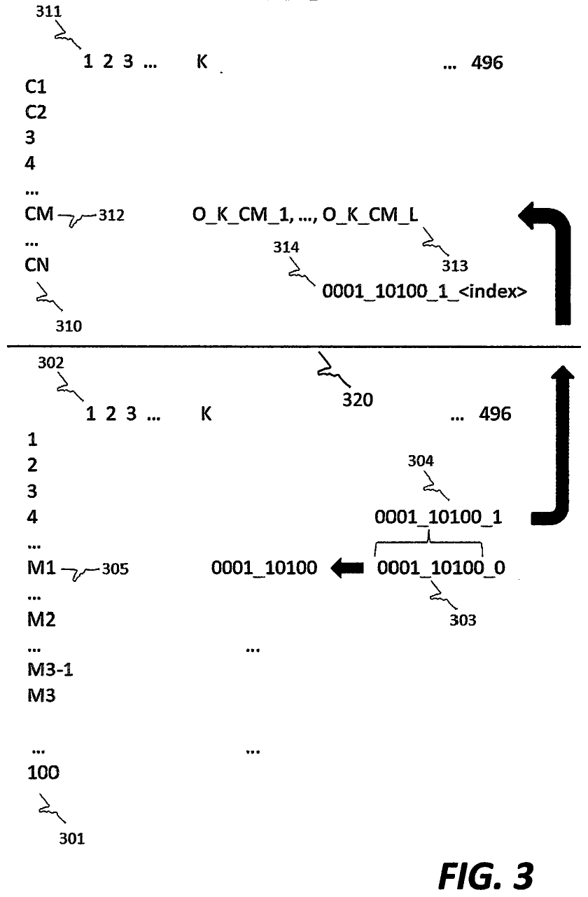

Discussions and examples for Scheme 2 will be disclosed having primarily RI class 9 as origin class. Using upper classes as the origin class, will lead, similarly as Scheme 1, to wider variations and distributions, which are beneficial for compression for similar reasons as discussed at Scheme 1. Scheme 2 has commonality with Scheme 1-only the differences will be outlined below. FIG. 3 is used to facilitate this part of the disclosure. In FIG. 3, the specifics for this part of the disclosure that are relevant to the origin class are detailed below line 320, while the specifics for the target class are detailed above line 320.

For the origin class, below line 320 in FIG. 3, in the 496 (columns 302 in FIG. 3) by 100 (rows 301 in FIG. 3) matrix, function of slice size, an entry E1 (305 in FIG. 3) with zero or minimal occurrences is located. Be this entry located at the intersection of pair (column) k and member M1 (row M1) in the matrix. For better understanding, say that the entry E1 represents, in the pairing range of every successive group of 32 PS in the current IFDS slice, the pair between PS 4 and PS 27 (i.e. matrix column 4_27, which is referred to as column k). Member M1 (row M1) consists of RI of four bits 0001 (for PS 4) and RI of five bits 10100 (for PS 27), i.e. it is a 4_5 RI pair class 9 member. In Scheme 1 implementation, this member was receiving an alternate 9 bit representation. In Scheme 2 implementation, the two components of the member remain unchanged on their position, with the only adjustment that if the member has non-zero occurrences, the second RI in the pair (here the five bit RI) receives a “_0” extension (i.e. it becomes 10100_0). If the member has zero occurrences, the two RIs remain as is without any adjustments. In this example, the 0001_10100 construct of the two RIs for that pair does not show up, so the nine bit construct becomes available for use in the target class.

As mentioned, for non-zero occurrences, if the two RI of member M1 would be put together, they would form the unique ten bit construct 0001_10100_0 (303 in FIG. 3). Given that this unique construct is identified in the matrix, at the pair (column) member (row) intersection, the 0001_10100_1 (304 in FIG. 3) becomes also in existence as a unique construct. In this scheme, this unique construct will be used to describe members of a target (upper class), rather than being used in conjunction with another member E2 to create gain using E3 (as in Scheme 1). So, in Scheme 2, E1 and a target class is needed, rather than a triplet as in Scheme-1.

Concerning the target class (above line 320 in FIG. 3), consider for example class 19 as the target class. Before detailing the said class 19 target class for this example, the big picture is introduced. A so called target matrix from where a target class can be chosen, is formed. This target matrix is of size 496 (same size as the matrix for the origin class, columns 311 in FIG. 3) by CN (rows 310 in FIG. 3). The columns in the target matrix have exactly the same significance as in the origin matrix, i.e. they represent the pairs created within the pairing range; clearly, these pairs apply for all classes. Each row in the target matrix represents a class, where such class is of larger number of bits that the origin class. For example, if the origin class, for which the origin matrix is built, is for class 9, the possible target classes (rows) in the target class matrix is 10 and above. For practical reasons, it makes sense to use a tighter range of classes that can be candidates, such as between 4 and 19 classes above the target class (in the class 9 example, this translates that the target matrix rows are in-between class 13 and class 28). For each row in the target matrix, such as the class 19 row, the number of occurrences for each of the 496 pairs for that class, are summed and entered in the matrix at that position. This sum of occurrences is entered in term of several divisions, where each division represents a sum of well defined members within that class, as detailed next using an example. In FIG. 3, these divisions are suggested by 313, i.e. O_K_CM_1 to O_K_CM_L, where O_K_CM_I means the sum for members of division I for class CM at pair K.

Class 19 has 1138 members (of 19 bits). While these class 19 members (target class members) are summed and entered as a sum in the target matrix (on a few divisions basis), they must not loose their individuality, so that at decompression they are fully restored. That is why, in the compressed output data stream, they are entered as a combination as shown by 314 in FIG. 3, namely comprising of 304 followed by an index, where the index comprising a counter (as detailed next).

To explain the above considerations, for non-zero occurrences, the above unique ten bit construct (0001_10100_1) can describe 256 members of class 19 (using an eight bit counter), at a gain of 1. The original descriptions of these 256 members are released, and when combined with the original description of other 256 members, produces a gain of 1 as well. Therefore, 512 members of 1138 (or about 50%, for simplicity of the discussion) produce a gain of 1, where 256 members are described as shown by 314 in FIG. 3, and 256 are each described by combining two original descriptions of 19 bits each, resulting in one unique description of 18 bits. When the members have alternate representation, two consecutive such alternate representations of 19 bits each where just the last bit changes, (such as in block 205 of FIG. 2, where two nine bit representations are combined to obtain an eight bit representation) are combined and an 18 bit representation is obtained. When alternate representation is used, such alternate representation is used for all classes (origin and target), for the columns that have the entries, similar to Scheme 1. When no alternate representation is used, the only difference (and challenge) is to combine two 19 bit class members to obtain a unique equivalent 18 bit representation. This is a challenge since the two 19 bit members usually have no correlation. A direct solution to this challenge is that the 1138 members of the class are by convention partitioned in consecutive pairs, with the first member in each pair being represented as described by 314 in FIG. 3, and the second member being described by the second member original representation with the last bit dropped. To avoid conflicts when dropping this last bit (such as when combining a 15 bit RI with a four bit RI, when the four bit RI may be in one case 0000 and in another case 0001 and by dropping the last bit in the four bit RI we get 000 in both cases), such cases will be by default part of a said “by convention” partition of pairs.

In conclusion, for the non-zero occurrences case, about 50% of class 19 target members provide a gain of 1, while the other about 50% of members provide zero gain. There are therefore two divisions of class 19 members in this case, and one bit is added as cost to choose which of these two divisions is used.

For the zero occurrences case, the discussion is very similar. The only difference is that the above unique nine bit construct (0001_10100) can describe 512 members of class 19 (using a nine bit counter), at a gain of 1, i.e. about 50% of class 19 members. The other 50% of class 19 members will provide a gain of 1 by combining the two original descriptions, using a similar procedure as exemplified above in the two possible implementations. Similarly, alternate representations or not, can be used. In this case, there are no divisions (the entire class provides gain, since all members are covered).

Since a class 19 member has a 210 lower probability of occurrence than a class 9 member, when accounting for all class 19 members (1138 or about 210 for simplicity of this discussion), it is apparent that in an IFDS slice of size n*16,000 PS where each class 9 member has nominally n occurrences, there are approximately n total class 19 members occurring for that respective pair (column) to which E1 belongs to. Since the non-zero (zero) occurrence case covers 50% (100%) of class 19 members at a gain of 1, it translates into having about n/2 (n) nominal members that will produce a gain of 1.

### Example

a. For a non-zero occurrences entry and an IFDS slice of 256*16,000PS, and a class 9 E1 on column k at member M1 having N1 occurrences, where member M1 targets class 19 as the target class, the compression condition, in nominal terms, is N1<128-cost, where cost is 9 bit (to specify matrix column) plus 7 bit (to specify matrix row) plus 1 bit to specify one division of 512 members (out of the 2 that are possible). This translates that Scheme 2, as is now, will produce gain if there is an entry in the 496 by 100 matrix (49,600 possibilities) that has the number of occurrences N1 smaller than 111, when the nominal is 256.
b. For a similar scenario but a zero occurrence entry, the compression condition becomes “cost <256”, with cost=16 (9 for the column, 7 for the M1), condition which obviously is always true. But obviously having a zero occurrence entry for a slice of 256 average occurrences has a low probability. The zero occurrence entry scenario works on a much smaller IFDS slice, such as a 16*16,000 PS slice, where the probability to have a zero occurrence entry anywhere in the 49,600 matrix is good. The additional condition is that for the column where the zero occurrence entry resides, the target class must have more than 16 occurrences (when the average is 16), conditions which again has a good probability.

The probability of Example (a) above is a function of the IFDS content distribution, being conditioned essentially to have one entry out of 49,600 possibilities with a minimum of 110 occurrences from a nominal of 256. This probability can be further improved, based on the following considerations:
i. The gain produced by the target class is at nominal value. But the content of the target class in itself is subject to a distribution, i.e. the 256 nominal content of class 19 varies.
ii. In the “cost”, one bit is specified that will select one of the two divisions of 512 class 19 members. The content of these two divisions in an arbitrary IFDS is subject to a distribution, and the chosen division is the one that has the largest content, therefore the largest than the nominal value of 128.
iii. The one bit part of the “cost” can be extended. For example, 16 divisions of 64 members each can be created, out of which eight divisions are chosen as active. The idea is that nominally, each of the 16 divisions will have 16 members that produce gain, but since the 16 divisions are automatically subject to a distribution, the eight divisions with the highest content will be chosen. The “cost” increases from one bit to C16_8 (combinations of 16 taken 8), which requires about 14 bits, but if the eight chosen divisions will have a content of average 19 (instead of the nominal 16), which has a good probability, then the gain becomes 8*19 (from the eight divisions) minus 14 (the cost to choose the eight divisions)=138 (that is instead of 8*16−1=127, which would be for the nominal values), therefore a net gain of 11 out of this technique.
iv. Use a different class as a target class. Any class can be a target class. Class 15 is exemplified next. Class 15 has 872 members, and each member has a 16× larger probability of occurrence than a class 19 member. A non-zero occurrence case will have 32 members of class 15 at gain of 1, meaning that there are 28 divisions to cover all 872 members. Out of these 28 divisions, one is chosen as active. In the same 256*16,000 PS slice, there will be 16*256 members that occur in each pair (matrix column). Out of these, 1/28 will produce gain, i.e. about 144. Five bits will be the cost to specify one of the 28 divisions, resulting in a nominal net gain of 139. This nominal gain can be improved with any of (i.), (ii.), (iii.) above, or extensions and variations of these. Note that a different target class may produce different results (139 nominal for class 15 versus 127 nominal for class 19).

Improvements i-to-iv above can be used for the zero-occurrence entry scenario, with adjustments that are obvious for the person skilled in the art.

### BDCD_s3: BDCD Scheme 3

Scheme 3 is an extension scheme that applies both to Scheme 1 and Scheme 2 and deals with large groups of same type bits (either all 0 or all 1), specifically creating compression gain for such groups. If Scheme 3 is not applied (maybe the distribution in the IFDS slice does not contain such groups of same type bits, or for any other reason), the compression with Scheme 1 or Scheme 2 remains as is. Scheme 3 enhances the compression and is applied at the same time as Scheme1 or Scheme2 is applied.

BDCD_s3 works the same for Scheme 1 and Scheme 2, but differs as a function if the implementation is using the alternate representation for RI pairs, or not, as disclosed above. BDCD_s3 is useful in providing compression for large groups of same type bits, with the magnitude of such compression being essentially linear with the number of bits in such groups of same type bits. As disclosed below, BDCD_s3 can be optimized to compress groups of same type bits where this group is of relatively low number of bits (such as for example 15 or even lower), but the restrictions increase as this number of bits in such groups gets smaller. Therefore, it is preferable to employ BDCD_s3 for larger such groups of bits, such as larger than 25 or 30.

As an overview, when BDCD_s3 is employed, a group of same type bits that is desired to produce compression must be included in one of the column of the entries of the respective scheme (Scheme 1 or Scheme 2), otherwise that group is not processed (is left as is). The compression gain produced by that group of same type bits that is included in an entry column of Scheme 1 or Scheme 2 will increase the compression gain of the respective scheme. All these aspects are detailed next. There is a tremendous amount of variations and optimizations for BDCD_s3 applicable for both Scheme 1 and Scheme 2—these variations and optimizations do not change the fundaments of the disclosure, are apparent to a person skilled in the art, and are not possible to be outlined entirely in this disclosure due to the amount of details which are not relevant for the substance of the disclosure, details that can be easily inferred by a person skilled in the art. BDCD_s3 is disclosed for Scheme 1 when implemented with alternate representation, and for Scheme 2 when implemented without alternate representation for RI pairs, using examples to cover the fundaments. BDCD_s3 works the same for Scheme 1 and Scheme 2 when implemented the other way around, and therefore the disclosure is covering such obvious variations fully.

BDCD_s3 for Scheme 1 Implemented with Alternate Representation for RI Pairs

To exemplify, the IFDS slice size that is considered for the exposition in this disclosure is 256*16,000 PS. The exposition will also exemplify other specific options, such as when class 9 RI pair is chosen as the contained class for Scheme 1. In a real implementation, all these options can be varied dynamically and freezed when compression gain is obtained.

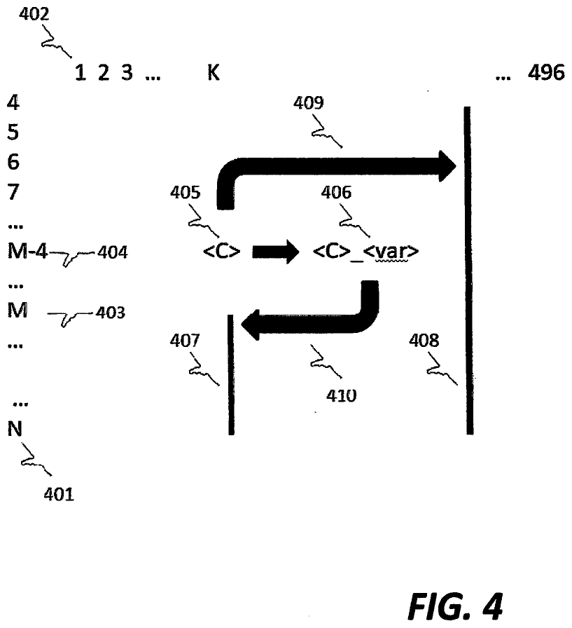

As mentioned, BDCD_s3 will be disclosed for Scheme 1 when this is implemented using alternate representation of RI pairs. Since, theoretically, groups of same type bits up to the size of the IFDS can occur, this alternate representation can be demanding practically. BDCD_s3 will also address this demanding representation by limiting this representation to an upper limit, as disclosed next. Across disclosing BDCD_s3 for Scheme 1 in the above mentions conditions, reference will be made to FIG. 4.

A requirement for BDCD_s3 is that the group of same type bits that is eligible to be compressed must belong to a pair belonging to one of the columns carrying the said entries. Such a group is represented by an RI. Since every entry is an RI pair that belongs to one of the 496 columns, the RI for said same type bit group is paired with another RI, where this another RI can be any RI from class 4 to the theoretical infinity. There are several restrictions related to this another RI. These are outlined below for a nominal, theoretical stance. It is noted that multiple variations and optimizations are possible.
i. This another RI must not be an RI of a same type bit group that is also considered for compression
ii. It must not be part of part of a specific RI pair class
iii. The lower limit of number of bits in the same type bit group (i.e. the RI class of this group) is chosen such that the pair (matrix column) created between the RI representing the group of same type bits and the another RI in the considered pairing range will not contain any pairs belonging to the part of a specific RI pair class mentioned at (ii) above.

The example provided below exemplifies the restrictions outlined above, based on mathematical derivations from data outlined in this disclosure and UPA, and progressively discloses the embodiments specific to Scheme 3. These mentioned derivations are not literally presented here, since they are apparent to a person skilled in the art and the data presented is sufficient to describe the fundaments of the disclosure. The discussions are referred to FIG. 4. In FIG. 4, a matrix is shown, where 402 are the 496 columns representing the C32_2 pairs that can be formed in a pairing range. 401 in FIG. 4 signifies the lead RI of a pair, where the lead RI is the RI from the largest class in that pair. For example, if a pair is formed between a class 15 RI and a class 4 RI on column K, it is entered in the FIG. 4 matrix in the row labelled 15. The lowest lead RI can be 4 (the lowest RI), as shown in FIG. 4, where the first row is 4.
a. For a 256*16,000 slice size, the lower limit for a group of same type bits that meets the above restrictions for the worst case distribution is 20 (represented by member M shown as 403 in FIG. 4). In this case, M=20 is shown as the lead RI in a pair. This worst case distribution (described below) has a very low probability, but it is described below because this distribution has a very important theoretical significance for this part of the disclosure. While for realistic distributions (the bulk of distributions) a notably lower than 20 same type bit group is possible, choosing a lower same type bit groups, may, for certain distributions, disable any possible choice of entries in Scheme 1, or introduce significant restrictions (as shown below) leading to no possible compression for that respective IFDS slice. On the other hand, choosing a lower same type bit group may produce a stronger compression for specific distributions within the respective IFDS slice, so, a trade-off is obvious in-between having a stronger compression or having no compression for slices with specific unfavourable distribution. Such trade-off criteria are straight-forward definable to a person skilled in the art, and are not discussed in this disclosure. Groups of same type bits of 20 and higher will be exemplified next, just to show the critical, low probability situation, which is relevant for the disclosure.
b. In order to implement this compression gain for groups 20 and higher, one class 16 RI pair alternative representation is reserved (four units below the RI of 20, where this number four will become apparent why chosen as such, below). By reserving this one class 16 representation (shown in FIG. 4 as 404), derivations show that class 26 and above RI pairs will remain without representation. Class 26 and above RI pair class is the specific RI pair class mentioned at (ii) in the restrictions above, for this example case, as not being “part of a part of RI classes”. The “part of a part” formulation is clarified next. Below is disclosed how to deal with these classes.
c. Class 26 can be formed as pairs of RIs such as 22-4 (4-22), 21-5 (5-21), 20-6 (6-20), 19-7 (7-19), 18-8 (8-18), 17-9 (9-17), 16-10 (10-16), 15-11 (11-15), 14-12 (12-14), and 13-13, where the RI members of each class (see FIG. 1) are used for these pairs. The pairs 22-4, 21-5, and 20-6, with their duals, do not exist (22-4), or have a lead member (21, 20) less, because groups of same type bits greater or equal than 20 are treated differently. Starting with lead RI 19 and below, all members contribute. Similarly can be discussed for each of classes 27 and above.
d. In an arbitrary input string, any content (any pair) occurs, and therefore all pairs must have representation. Since, by reserving one class 16 RI pair alternative representation, class 26 and above RI pairs remain without representation, a solution for these classes to get representation must be developed. Providing such solution to get representation for these classes is a key embodiment of this disclosure for Scheme 3.
e. As mentioned, for a large group of same type bits to be compressed, this must be on the same column as the said entries. One said solution to provide representation for class 26 and above is, to not allow, in that column, one or more RI classes. For the considered example (20 and above same type bit groups considered for compression in a 256*16,000 IFDS slice), not allowing (or forbidding) RI class 19 on said column is sufficient to provide representation for everything else. Forbidding class 19 RI means that pairs 19-7 (7-19), 19-8 (8-19), 19-9 (9-19) . . . 19-19, and 19-20 (20-19), 19-21 (21-19), these two without the 20 and 21 same type bit group RI, cannot occur on that column. Clearly, pairs (22 and greater)-19 cannot exist since (22 and greater) RIs are only RIs of same type bits.
f. In a slice of 256*16,000, nominally, 24 occurrences of a class 19 RI can occur. If each of these 24 occurrences, in the 256*256 pairing ranges of 32 that exist in the slice, occupy a distinctive position of the 32, means that 24 positions out of 32 cannot form a pair in the original 496 by 100 matrix, which means that the original 496*100 matrix is restricted to 28 by 100, where the 28 columns represent C8_2 (instead of the original C32_2). That means that both the entries for Scheme 1 and the 20 and greater same type bit group to be compressed must be on one of these 28 columns of the restricted matrix. Even a so called lock condition can be formed, when there are 32 (instead of 24) occurrences of class 19 RIs in the 256*16,000 slice, and all these 32 occurrences occupy one distinctive position of the 32 positions of the pairing range across the 256*256 pairing ranges in the slice. Note that such distributions, as exemplified above, have low probability, since such distributions have been named to distinctively occupy one position per occurrence in the pairing range. However, even with less restrictive distributions, the consequence of having a restrictive matrix for the entries is not desired.
g. There are two solutions to not having such a restrictive matrix for the entries; one is to have a smaller IFDS slice, and the other one is to have a larger minimum same type bit group. For example, if the slice is 64*16,000 (instead of 256*16,000), the worst case number of forbidden positions in the pairing range become 6 (instead of 24), and the number of available columns in the 496 by 100 matrix becomes 325 (C26_2) by 100 instead of 28 by 100. If the same type bit group is 25 and larger (instead of 20 and larger), then a 21 bit alternate representation is reserved (instead of the 16 one), 24 and 23 classes of RI are forbidden from the columns with entries and 25 and larger same type bit groups to be compressed, which for a 256*16,000 slice generates no restrictions up to one position in the 32 pairing ranges corresponding to no restriction up to 31 restricted columns in the 496 by 100 matrix (i.e. 465 columns are unrestricted). Doing even higher that 25 and larger groups reduces the probability of having these 31 restricted columns further.
h. The real value of Scheme 3 is to provide means to efficiently compress groups of large number of bits (such as greater than 30), and to simplify and limit the possible pairs of RIs (which without Scheme 3 would extend to a theoretical infinity), so, considering compressing groups of same type bits smaller than 30 is of little value unless for a small number of unique distributions within the considered IFDS slice. The theoretical perspective described above covers full disclosure of the situations in such cases.
i. In FIG. 4, any forbidden columns in the 496 by 100 matrix, as described above, are symbolically shown as line 408.
j. Given that all 20 and larger same type bit RI are part of compression according to BDCD_s3 but up to class 21 RI pairs there are other RI than the same type bit RI, the last pair that can exist when BDCD_s3 is applied is pair class 42 (resulting from pairing two class 21 RIs). If the RI for the minimum same type bit group considered for compression would be greater than 21 (such as 25), then the last pair that can exist would be double that RI (such as 50).
k. Considering, as described above, that a number of columns in the matrix of FIG. 4 are forbidden and that the non-forbidden column K as shown in FIG. 4 is the chosen column for the entries of Scheme 1, then on this column, the 16 bit reserved representation is represented by code <C> indicated by 405 in FIG. 4. Using this code <C>, all the pairs containing a group (RI) of 20 same type bit and larger are formatted as 406 in FIG. 4. The said such formatted pairs are symbolically shown as line 407 in FIG. 4 with arrow 410 showing that the 406 formatting describes such formatted pairs. Arrow 408 in FIG. 4 symbolizes that the code <C> and the forbidden columns are related, code <C> conditioning these columns. The formatting details are:
   <16 bit reserved representation><1 bit><variable bit> is represented by 406 in FIG. 4
      <16 bit reserved representation>—as detailed at (b) above, is the code <C> in FIG. 4
      <1 bit_1><1 bit_2><variable bit> is <var> part of 406 in FIG. 4, where:
      <1 bit>—a value of 0 (1) indicates that the same type bit group is the first (second) position in the considered pair, such as position 5 (position 27) in the 5-27 pair (column).
      <variable bit> is used to describe what is the group of same type bit, such as:
         00->20 bits of same type—gain 1
         01->21 bits of same type—gain 2
         10->22 bits of same type—gain 3
         11_00->23 bits of same type—gain 2
         11_01->24 bits of same type—gain 3
         11_10->25 bits of same type—gain 4
         11_11_000->26 bits of same type—gain 2
         . . .
         11_11_110->32 bits of same type—gain 8
         11_11_111_<7 bits>->33-to-160 bits of same type gain 2-to-128
         11_11_111_<seven 1s>_<128 bits>->161-to-2¹²⁷ bits of same type—gain 2-to-2¹²⁸
l. The RI for the group that creates a pair with the RI for the groups of same type bits formatted as disclosed at (k) above will be written in raw form in the output immediately after the format detailed at (k) above.

As mentioned, a tremendous amount of variations of the disclosed embodiments are possible, obvious to a person skilled in the art.

BDCD_s3 for Scheme 2 Implemented without Alternate Representation of RI Pairs

The implementation without alternate representation of RI pairs features entirely the same concepts as the implementation with alternate representation, disclosed above, the differences being only in some implementation details. BDCD_s3 for Scheme 2 is disclosed for the implementation without alternate representation of RI pairs (called for the rest of the disclosure, for simplicity S3S2) in order to outline said differences and fully disclose the implementation in both cases. There is no restriction to implement BDCD_s3 for Scheme 2 with the alternate representation of RI pairs, in this case the implementation procedure described above for Scheme 1 being applied. Similarly as above, for the BDCD_s3 for Scheme 1 implemented with alternate representation for RI pairs (called for the rest of the disclosure as S3S1 for simplicity), there is a tremendous amount of variations and optimizations that are possible, and similarly, only the fundaments are described in this disclosure, for the same reasons as mentioned above. Similarly, a worst case example will be used.

A similar derivation for a lowest same type bit group that would satisfy a lock condition will give, in similar conditions as above, a size of 22. The lock condition is, similarly, a low probability condition, and similarly as above, multiple trade-offs can be made between the probability of having a distribution subject to a lock condition (that would render an IFDS slice not to compress) and a bulk (high probability) distribution subject to a lower than 22 same type bit group that will compress. These trade-offs are apparent to a person skilled in the art, and will not be detailed here.

The theoretical steps for S3S2, in a parallel with S3S1 (to insure appropriate comparison and understanding) are:
1 For a 256*16,000 slice size, the lower limit for a group of same type bits that meets similar restrictions as for S3S1 for the worst case distribution is 22. Similarly, this worst case distribution (described below) has a low probability. All other considerations are similar as described at S3S1. Differences for S3S2 for groups of same type bits of 22 and higher will be exemplified next.
2 In order to implement this compression gain for groups 22 and higher, the RI of four units below the chosen number (22−4=18) for the same type bit group (i.e. the RI for the 18 same type bit group) is reserved. Note the first major difference between an implementation with alternate representation (S3S1) and one without (S3S2). For the one with, a specific RI pair is reserved, while for the one without, a specific single RI is reserved. The consequences of this difference will become apparent below, as the disclosure continues. By reserving this class 18 RI, all groups of 18 same type bits that show up in the IFDS slice will remain without representation. How to deal with this situation is disclosed below.
3 The reserved RI of class 18 mentioned above will be paired with another RI which can be of any class, from class 4 to infinity. Coding such pair is specific, and consists in the reserved class 18 RI followed by an index representing the other RI, where the number of bits in the index must be the same as the number of bits in the other RI, and where the index must cover all other possible RIs in such a pair such that the gain/loss after coding such pair is zero. A straightforward derivation in coding such pair in accordance to the above will show that, in the pair, the class 18 RI must be avoided to be paired with all class 4 RIs (five of them) and six out of 10 class 5 RIs. All other pairs between the reserved class 18 RI and the other RI when this other RI is indexed, as described above, for the remaining four out of 10 class 5 RI and all class 6 RI and above, can be coded in accordance to the above remarks and conditions.
4 While the above solution is implementable, forbidding the reserved class 18 RI to pair with class 4 RIs and six of the class 5 RIs is not practical, because in a pair (column) of the 496 by 100 matrix, for a practical IFDS slice size, it is practically impossible not to have a class 4 or a class 5 RI. Therefore the practical solution is, similar to S3S1, to forbid the columns with entries and same type bit groups to be compressed from having occurrences of 18 same type bit groups.
5 Given the above conclusion, in the subject IFDS slice (256*16,000), the reserved class 18 RI nominally occurs sixteen times. That is equivalent to the said number of occurrences of the said forbidden RI pair class for S3S1. Similarly, that will leave a theoretical worst condition space of 16 to work with in the pairing range, and a space of C16_2 by 100 (120 by 100) for the said entries in the said matrix. Similar trade-offs and notes as described for S3S1 exist. To give the same additional example as in S3S1, reducing the slice size to 64*16,000, will forbid 4 of the 32 positions in the pairing range and 118 columns in the 486 by 100 matrix (having 378 by 100 available for choice of entries and 22 and greater same type bit groups). Similarly, increasing by five the same type bit group (27 instead of 22, as for S3S1 was 25 instead of 20), leads to a 50% probability (for the 256*16,000 slice) to have the theoretical one out of 32 positions to be forbidden and therefore 31 columns forbidden in the 496 by 100 matrix.
6 The coding format for groups larger or equal than 22 bits of same type, follows the same format and rules as for S3S1. All considerations and notes mentioned above hold as well.
   a. <18 bit reserved RI><1 bit><variable bit>
      i. <18 bit reserved RI>—as detailed at (2) above
      ii. <1 bit>—a value of 0 (1) will indicate that the same type bit group is the first (second) position in the considered pair, such as position 5 (position 27) in the 5-27 pair.
      iii. <variable bit> is used to describe what is the group of same type bit, such as:
         1. 00->22 bits of same type—gain 1
         2. 01->23 bits of same type—gain 2
         3. 10->24 bits of same type—gain 3
         4. 11_00->25 bits of same type—gain 2
         5. 11_01->26 bits of same type—gain 3
         6. 11_10->27 bits of same type—gain 4
         7. 11_11_000->28 bits of same type—gain 2
         8. . . .
         9. 11_11_110->34 bits of same type—gain 8
         10. 11_11_111_<7 bits>->35-to-162 bits of same type—gain 2-to-128
         11. 11_11_111_<seven 1s>_<128 bits>->163-to-2¹²⁸ bits of same type—gain 2-to-2¹²⁸
7 Similarly, the RI in the pair with this group of same type bits is written in the output, in raw format, after the format of the group, described at (6) above.

Similarly to S3S1, a tremendous amount of variations of the disclosed embodiments are possible, obvious to a person skilled in the art. In conclusion when implementing BDCD_s3 without alternate representations, the key differences from the implementation with alternate representations, are:
A specific single RI is reserved, versus a specific alternate representation of an RI pair.
The forbidden columns in the entries matrix are based on forbidding all pairs that contain that specific reserved single RI only, versus forbidding all pairs of one or more well defined RI classes.

### BDCD_s4: BDCD Scheme 4

Scheme 4 is another extension scheme that applies both to Scheme 1 and Scheme 2 and deals with specific optimizations to extend the scope of Scheme 1 and Scheme 2.

### BDCD_s4 for Scheme 1

An important limitation of Scheme 1 is that the three entries must be on the same matrix column (belonging to the same one of the 496 pairs in the considered example). Scheme 4 eliminates this limitation, such that for example entry 1 will represent pair 34 member 3, entry 2 will represent pair 201 member 47, and entry 3 will represent pair 446 member 97. In comparison, discussing the same example, Scheme 1 would have required that the three members of the three entries, member 3, 47, and 97, belong all to pair 201 for example. The notable difference between Scheme1 and Scheme 4 becomes apparent, respectively for Scheme 1 three out of 100 entries with 496 versions can meet the compression condition, while for Scheme 4 three out of 49,600 entries (single version) can meet the compression condition. Clearly, the probability to meet three out of 49,600 is larger than to meet three out of 100 with 496 versions. The great advantage of BDCD_s4 is that two absolute minimums in the 49,600 entries matrix and one absolute maximum in the 49,600 matrix are enabled to be used. The discussion above is exemplified for class 9 RI pair. For larger RI pair classes, such as class 10, or class 11, the difference between Scheme 1 and Scheme 4 increases as the RI pair class order increases, in Scheme 4 favour. Scheme 1 implemented with alternate representation of pairs is used below, for continuity of the disclosure exposition. As mentioned, Scheme 1 can be used without alternate representation, and Scheme 4 has no restrictions from that point of view. In fact, BDCD_s4 for Scheme 2 will be disclosed for the without representation implementation.

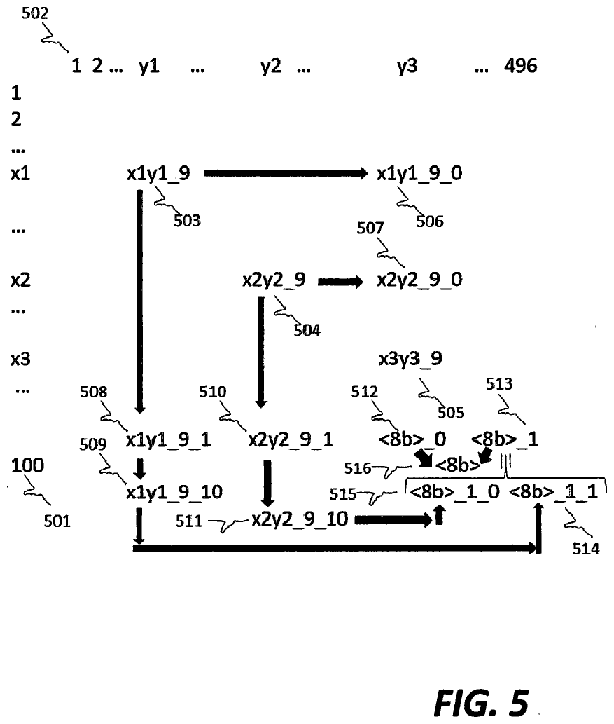

To implement Scheme 4, the following example is discussed. FIG. 5 is used as a visual aid to better understand the disclosed embodiments. In FIG. 5, the 496 (columns 502) by 100 (rows 501) matrix is shown. In the description, the following convention is used: member x of pair y for RI pair class z will be called x-y-z. Therefore, entry 1 (x1-y1-9) and entry 2 (x2-y2-9) are the two entries with minimum occurrences, and entry 3 (x3-y3-9) is the entry with maximum occurrences. If x1y1_9 (503 in FIG. 5) is the alternate representation of entry 1, x1y1_9_0 (506 in FIG. 5, where a zero is added to the 9 bit representation) will be used to represent entry 1 occurrences at a loss of 1 bit per occurrence. x1y1_9_1 (508 in FIG. 5) will be used to represent the same order class 10 RI pair alternate representation, be that called x1y1_9_10 (509 in FIG. 5), releasing it. There is no gain or loss by this x1y1_9_1 to x1y1_9_10 swap. Representing a class 9 originated representation (x1y1_9_1) with a class 10 representation (x1y1_9_10) is possible and insures a unique correspondence because class 10 has more members than class 9 (220 vs. 100). Similarly for entry 2, x2y2_9_0 (507 in FIG. 5) will represent entry 2 occurrences at a loss of 1 bit per occurrence, and x2y2_9_1 (510 in FIG. 5) will swap x2y2_9_10 (511 in FIG. 5) at no gain or loss, releasing x2y2_9_10.

For entry 3 (x3y3), the following applies. x3y3, just like x1y1 and x2y2, is represented by 9 bits, with the format <8 bits>_0 or <8 bits>_1, where <8 bits> is a given, fixed 8 bit configuration. Say in this example that x3y3 is represented by <8 bits>_0, or <8b>_0 (512 in FIG. 5). In order to provide a gain of 1 for every occurrence of x3y3, the goal is to represent x3y3 by the <8b> configuration only. Since x3y3 is represented by <8b>_0, that means that <8b>_1 must be released, so that <8b>_0 combined with <8b>_1 creates <8b>. The <8b>_1 (513 in FIG. 5) is the neighbour pair (column), on the same member to <8b>_0 with the alternate representation having only the last bit different. In order to release <8b>_1, the available 10 bit representations x1y1_9_10 and x2y2_9_10 will be combined to generate a unique 9 bit representation that will represent all the occurrences of the original <8b>_1, releasing <8b>_1 (this block is shown in FIG. 5 by <8b>_1_0 (515 in FIG. 5) being swapped by the available x2y2_9_10 and <8b>_1_1 (514 in FIG. 5) being swapped by the available <x1y1>_9_10, releasing both <8b>_1_0 and <8b>_1_1, therefore by combining now both the available <8b>_1_0 and <8b>_1_1 creates the unique 9 bit representation to represent the original <8b>1 occurrences making the original <8b>_1 to be available). Combining <8b>_0 with the available <8b>_1, makes <8b>_0 to be uniquely represented by <8b> (516 in FIG. 5), the target 8 bit representation. Accordingly entry 1, entry 2, and entry 3 are decoupled to be anywhere in the 49,600 entries matrix, while still keeping the same compression condition N3>N1+N2+cost. The cost however increases, and now consists in specifying the column and member for each of the three entries, i.e. 3*(9+7)=48 bits. Because of this cost, BDCD_s4 will start working for IFDS slices starting with 32*16,000, but 16*16,000 can be possible if an entry in the 49,600 matrix has more than (48 plus x1-y1_9 plus x2-y2_9 occurrences) occurrences.

A particular case is when there is an entry of zero occurrences in the matrix. In this case, only the zero occurrence entry and the maximum occurrence entry are needed. The cost is 2*(9+7)=32 bits. In this case, the scheme will work fairly common for a minimum IFDS slice of 16*16,000, but a slice of 8*16,000 can work if an entry in the 49,600 matrix has more that 32 occurrences.

### BDCD_s4 for Scheme 2

For Scheme 2, the limiting characteristic is that the entry in the origin class and the target class must be on the same matrix column. Similarly as for BDCD_s4 for Scheme 1, this limitation is eliminated, i.e. the entry for the origin class can be on one column and the target class can be on another column, with the benefits similar as described for BDCD_s4 for Scheme 1.

To use a similar example as discussed when Scheme 1 was disclosed above, same 0001_10100 member (discussed at Scheme 2 disclosure) is discussed in the zero and non-zero occurrence scenarios.

In the zero occurrences scenario, the 0001_10100 9 bit member configuration on column (pair) 4 becomes available for use towards a target class such as class 19. But the class 19 target class has maximum occurrences on column (pair) 201. In order to make the 0001_10100 (called M1) available configuration to work on column 201, the following procedure applies. The M1 occurrences on column 201 will be moved in the same position as on column 201 on column 4, being represented by the available configuration 0001_10100. The implementing hardware or software will see members M1 on column 4 and will know that these are occurrences from column 201, and in fact on the respective position, in column 4, are the next configurations represented in the string. This way, the M1 configuration becomes available on column 201, and is used for the target class, as described at BDCD_s2.

In the non-zero occurrence scenario, 0001_10100_0 (10 bit) configuration will be used to describe the M1 occurrences on column 4 at a loss of 1 bit per occurrence. The 0001_10100_1 becomes available and it will be used to describe the same order class 10 occurrences on column 4 (be the representation for these called M1_10 for the simplicity of this discussion). The original M1_10 representation on column 4 becomes available to be used towards the occurrences of a target class, such as class 19 target class.

However, similarly as discussed above, class 19 target class has the maximum occurrences on a different column (pair) such as column 201. Similarly as above, the M1_10 occurrences on column 201 will be moved in the same position as on column 201 on column 4. The implementing hardware or software will see members M1_10 on column 4 and will know that these are occurrences from column 201, and in fact on the respective position, in column 4, are the next configurations in the string. This way, the M1_10 configuration becomes available on column 201, and is used for the target class, as described at BDCD_s2.

When a known target class is always used, the cost for BDCD_s4 for Scheme 2 is, for zero occurrences, (column plus row specification for origin class) plus (column for target class). For class 9 that is 25 bits. If the target class is customizable, a few extra bits (say three bits for the choice option of eight target classes) plus possibly maximum three bits to choose a segment in a target class (as disclosed above) can be added. Therefore, the cost can be in-between 25 and 31 bits. That makes a 16*16,000 slice size a good probability and performance choice.

For non-zero occurrences, the cost increases with 1 bit for every occurrence of the consider entry in the origin class.

Similar considerations/improvements as disclosed at BDCD_s4 for Scheme 1 are applied here for both zero and non-zero occurrences. And similarly, multiple variations, optimizations, and scenarios can be developed and are obvious for a person skilled in the art, and these do not represent a limitation of this disclosure.

Four schemes and multiple options to create compression gain have been disclosed. In an implementation, the scheme/option scenario that provides the largest gain is chosen. The choice of scheme/option scenario is not necessarily a sole function on the gain value, but, dependent on the application as well. For example, applications such as audio telephony requires low latency in the audio stream which, applied to the present disclosure, would have the consequence of requiring small IFDS slices. One option to reduce the IFDS slice size for such applications, for this disclosure, is to employ default pairing schemes where cost to specify the said entries is eliminated, the cost in these default pairing cases being only a header to specify one of the possible default pairing schemes. As disclosed, BDCD_s2 is more suitable for small IFDS slices, but BDCD_s1 is appropriate for such a goal as well, when implementing entries with zero occurrences.

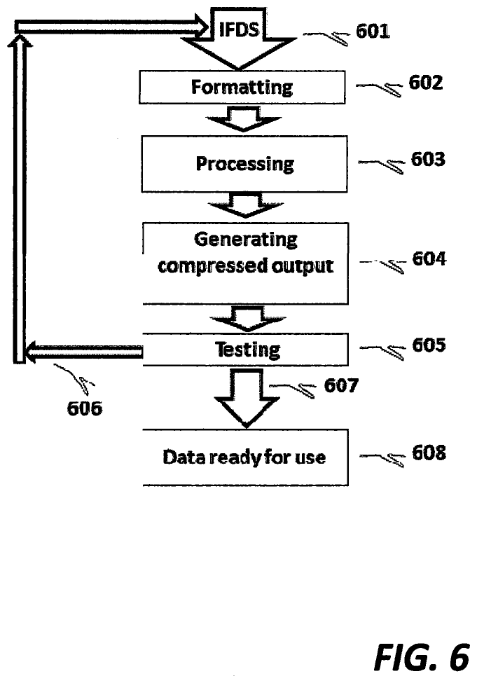

To conclude the disclosure, the data flow according to the disclosed embodiments is summarised in FIG. 6. The arbitrary input data string, IFDS, (601 in FIG. 6) is formatted (the 602 step in FIG. 6), where this formatting step comprising fully describing said IFDS using a set of well defined binary constructs. The formatted data string is processed (step 603 in FIG. 6), where this processing step comprising one or a combination of the disclosed schemes 1-to-4, specifically creating the set of well defined binary elements, the pairing ranges, partitioning the said IFDS in slices, characterizing the content of the said IFDS slices in term of occurring binary structures such as binary constructs and binary elements, creating the applicable matrixes, identifying the applicable sets of binary constructs, elements, and target classes. Based on the processed IFDS, an output is generated at step 604 in FIG. 6, where the generated output features compressed data, therefore a number of bits smaller than the input IFDS. The generated output may have the same number of bits as the input in cases when the processed and formatted IFDS does not meet any compression conditions for neither of Schemes 1-to-4 and none of their options. The generated output is subject to the testing step 605 in FIG. 6, where generally the testing step is testing if the number of bits in the generated output is smaller than a compression target or is smaller than a floor size below which compression may not have the desired efficiency. If the testing is not met, path 606 in FIG. 6 is followed, and the generated output is fed back at the input 601 for a new compression cycle. Any number of such cycles are possible. If the testing is met, path 607 in FIG. 6 is followed and the compressed data is ready for use (608 in FIG. 6).

The new matter of the CIP addresses several limitations of Scheme 1 to Scheme 4.

### Scheme 1 Applicable Discussion:

The ultimate goal of Scheme 1 in order to produce compression gain, as shown in the example that has been discussed for RI pair class 9, is to be able to uniquely amend the original 9 bit unique representation of an RI pair to a unique 8 bit representation, and by doing this, to obtain a gain of 1 bit for every occurrence of the altered RI pair representation. This has been shown possible by using a triplet of RI pair members of class 9 in the same pair (same matrix column), or a duplet of RI pair members of class 9 in the same pair (same matrix column). It has been shown that the duplet path increases the compression, but is more challenging to achieve because it requires as one of the two RI pair members of the duplet, called a first member, to be a member with zero occurrences in said IFDS slice for that chosen pair, while the other RI pair member of the duplet, called a second member, for the same matrix pair, has to have the largest number of occurrences for the smallest number of PS in said IFDS slice. This condition is challenging, because the probability to achieve a said first member with zero occurrences when a said second member with a large number of occurrences is a target, decreases as the number of occurrences of said second member increases.

### Scheme 2 Applicable Discussion:

As shown when Scheme 2 has been discussed and exemplified for the origin class as RI pair class 9 and target class as RI pair class 19, two versions are possible. The first version is when the considered RI pair member of the origin class for Scheme 2 has non-zero but minimal occurrences in said IFDS slice, while the second version is when the considered RI pair member has zero occurrences in said IFDS slice. For the target class, the largest possible number of occurrences for the RI pair members in the target class is the goal. Similar to scheme 1 but from a different perspective, a large number of occurrences in the target class decreases the probability to have an RI pair member with zero occurrences in the origin class. An RI pair member with zero occurrences in the origin class is highly desired because, as shown, it theoretically doubles the compression by covering double the number of RI pair members of the target class that can produce compression, as compared to when an RI pair member with non-zero occurrences is the only possible choice.

### Scheme 3 Applicable Discussion:

As shown, in order to generate compression gain for specific groups of same type bits, one RI pair member that is a member of an RI pair class of a number of bits equal to the smallest number of bits of an RI in said specific group of same type bits minus four must be reserved. By reserving an RI member (i.e. not using it to describe said IFDS) leads to an imbalance in fully describing an IFDS because an IFDS can be fully described when all uniquely developed RI members in said set of RI are used. The imbalance means that when the reserved member naturally occurs in said IFDS, a different representation for that natural occurrence must be developed, since the RI member that was describing that occurrence is not available, being reserved. To correct the imbalance, either said reserved RI member or a number of RI members of an upper class than the class of the reserved RI member, up to one or more full classes of RI, are restricted to occur in the RI pairs considered for compression. If, such a reserved RI member is in fact not reserved but rather does not occur in said IFDS, then the advantages are significant, and include:
All groups of same type bits of a number of bits greater or equal to the number of bits of said non-occurring RI member plus four, are covered for compression. This leads to groups of same type bits that are covered with a number of bits that is much smaller than in the reserved RI member case. For example, if the non-occurring member is of class 9, same type bit groups starting with 13 number of bits are covered (versus around 25 for the reserved RI member case). Covering groups with such a small number of same type bits has significant consequences, including by eliminating a significant number of RI pairs from classes between 17 and 44, where “eliminating” means that the original representation of such a significant number of pairs is because the RI of same type bits larger than 13 number of same type bits do not exist, therefore the pair in which these RI of same type bits are do not exist. For each eliminated pair, an existing pair of same number of bits as said eliminated pair produces a compression gain of one bit per each occurrence of said existing pair.
There are absolutely no restrictions in term of RI members or full classes that need to be restricted in the case for a reserved RI member. That is because the non-occurring member simply “does not occur”, and since it does not occur it does not need to have a representation because there are no naturally occurring members of that representation. As mentioned, the reserved member was required to be represented by a different unique member when it was naturally occurring in said IFDS, creating the imbalance discussed above.

### Scheme 4 Applicable Discussion:

Scheme 4 is nothing else but a relaxation of the conditions for Scheme 1 and Scheme 2, by allowing the triplets or duplets in Scheme 1 to be each in different matrix columns, or by allowing the RI member in the origin class and the occurrences in the target class to be in different columns. Therefore, Scheme 4 does not have any impact or does not attenuate any benefits that are described above for Scheme 1 respectively Scheme 2 from engaging a non-occurring member.

Note at this point that the availability, or existence, of a non-occurring RI member in any of the pairs of a class, such as one RI pair member out of the 100 class 9 RI pair members that is located in one of the 496 class 9 pairs of a class 9 pairing range, is extremely beneficial for all four schemes. Obviously, in a natural way, the existence of a non-occurring member in a pair is a matter of content and distribution of the respective IFDS slice. But relying on the natural occurrence of a non-occurring member is limiting the compression to only special distributions. It is desired to be able to compress using a non-occurring member for any distribution, and that is one invention brought in by this CIP: creating, or forcing - - - a non-occurring RI or RI pair member.

One of the important aspects of the invention is the extension of the definition of a pair. For a pairing range of 32 PS (RI), as discussed that it is the characteristic pairing range for class 9 RI pair, a pair, per the regular definition, is one of the C32_2 (496) possible pairs. For example, a pair is putting together the PS (RI) on position 4 with the PS (RI) on position 27 in the 32 position pairing range. If one of the 100 class 9 RI members is tracked in this pairing range, than the representation of this pairing range in term of the 496 possible pairs is one line, with 496 entries, where, out of these 496 entries, only zero, one, or maximum two entries has the tracked member and only zero to maximum one has the tracked member active, and that is because in the 32 pairing range there nominally is only one class 5 RI of interest, and only two class 4 RI of interest, making up the class 9 RI pair member of interest. If, for example, in that IFDS slice there are 8000 pairing ranges, i.e. 8000 times 32 PS, i.e. 16×496×32 PS, the representation in term of pairs is 8000 lines of 496 entries per line, i.e. a matrix of 8000 lines and 496 columns, with one line content in term of a tracked member as described above. The 16×496×32 PS IFDS slice will produce, nominally, for any of the 496 pairs (columns), 16 occurrences of the tracked class 9 RI member.

Since a pairing range has 32 PS (RI), 16 operational pairs can be created and considered, where the 16 operational pairs can be any of the 496 pairs that most closely match the goals of the respective scheme (such as zero occurrences for a member), with the condition that the 32 positions in the pairing range show up only once in one operational pair—this is called the operational pair condition. Choosing the 16 operational pairs is a computational task, where for every one of the 100 members an 8000×496 matrix is created, and 16 member/pairs that meet the goal of the scheme are selected, with the 16 pairs meeting the operational pair condition outlined above.

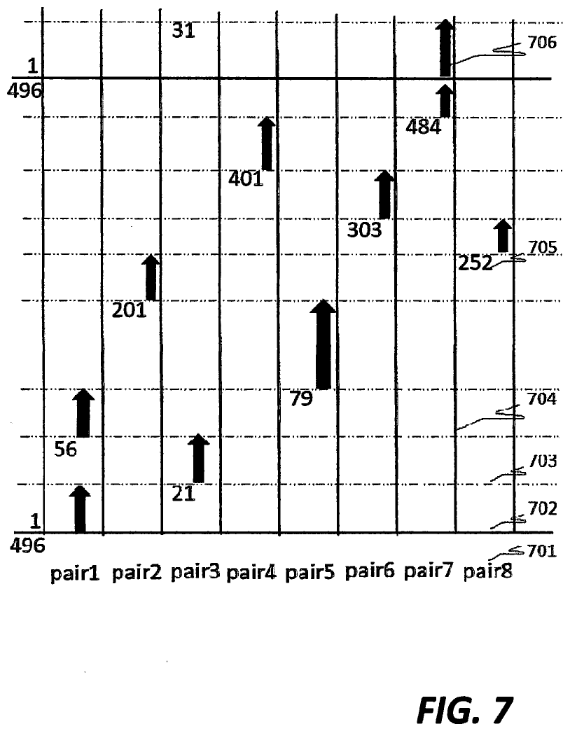

At this point in the exposition, all elements are available to introduce how to create, or force, a non-occurring member. In order to force a non-occurring member, a path over a group of 496 pairing ranges (characteristic for class 9 RI pair) is created in this disclosure. Regularly, such a path is a straight column pair. As introduced by this disclosure, this is a “hopping” path across multiple classic pairs, as outlined below. In this disclosure, this hopping path that forces a non-occurring member is called a first hopping path. To exemplify, consider an example matrix of 8 operational pairs (columns) by 497 lines (pairing ranges), as depicted in FIG. 7. As mentioned, nominally, a class 9 member occurs in one pair of the 496 possible pairs every 496 pairing ranges. In FIG. 7, it is depicted that a class 9 RI pair member of interest occurs in pair 1 at pairing range 56 (in short 1-56), in pair 2 occurs at pairing range 201 (2-201), then 3-21, 4-401, 5-79, 6-303, 7-484, 8-252, following in the next 496 group of pairing ranges at 3-31. Therefore, in FIG. 7:
i. 701 points to the row naming the eight considered pairs.
ii. 702 points to the solid horizontal lines delimiting two consecutive 496 pairing range groups where on the lower side of the horizontal line is the last location in the previous 496 group, i.e. 496, and on the upper side of the horizontal line is the first pairing range in the current 496 group, i.e. 1.
iii. 703 points to the dotted horizontal lines where the number on the lower side of the dotted line shows the location of the occurrence of the member of interest.
iv. 704 points to the solid vertical line delimiting the pairs.
v. 705 points to the numbers meaning the location of the occurrence of the member of interest.
vi. 706 points to the arrows which depict the path on which a zero occurrence path is formed. All these are better understood with the explanations provided below:
b. If a 496 group of pairing ranges is the first in the IFDS, then such a hopping path starts from pair 1, and this is depicted in FIG. 7.
   i. The hopping path is through pair 1 until the first occurrence of the class 9 member of interest in any of the eight considered operational pairs. In the above example, that will be in pair 3, pairing range 21. Conventionally, it is written that the first leg of the hopping path is 1_(1-21), i.e. in pair 1, the pairing ranges from 1 to 21, including 1 and 21. Note that the location 21 is included in pair 1, not in the pair where the occurrence of the member of interest exists, i.e. in pair 3. In other words, the hopping path “hops” in the pair where the occurrence of the member of interest happened, which is pair 3 in this case, immediately after the occurrence happened in that pair, i.e. starting with pairing range 22, the hopping path hops in pair 3.
   ii. The next leg of the hopping path is in the pair where the occurrence of the member of interest was noted, i.e. in pair 3, from pairing range 22 to 56, since in pair 1 the next occurrence of the member of interest is noted at pairing range 56. Therefore the hopping path continues with 3_(22-56)
   iii. Similarly, the hopping path continues with 1_(57-79), 5_(80-201), 2_(202-252), 8_(253-303), 6_(304-409), 4_(410-484).
   iv. The hopping path continues in pair 7, from pairing range 485 to the end of the current 496 pairing range group, and then continues in the same pair 7 in the next 496 pairing range group until the first occurrence of the member of interest in this group, which is at pairing range 31 of pair 3. Therefore, the next legs of the hopping path are 7_(485-496) plus 7_(1-31).
   v. Note how the said hopping path makes the transition between consecutive groups of 496 pairing ranges.
   vi. In short, the said hopping path is: 1_(1-21), 3_(22-56), 1_(57-79), 5_(80-201), 2_(202-252), 8_(253-303), 6_(304-409), 4_(410-484), 7_(485_496) plus 7_(1_31), and this hopping path has no occurrences of the member of interest included in it, i.e. this hopping path “forces” a non-occurring member of class 9 RI pair.

Not all members of interest can force a valid first hopping path, and that is a function of the content and distribution of the members in said IFDS slice.
1) For example, consider the following distribution of a member of interest in an IFDS slice of 8×496 (to match the case discussed in FIG. 7): 1-56, 2-201, 3-21, 4-401, 5-79, 5-123, 6-303, 7-484, 8-252.
2) The resulting hopping path will be: 1_(1-21), 3_(22_56), 1_(57-79), 5_(80-123), 5_(124-201), 2_(202-252), 8_(253-303), 6_(304-401), 4_(402-484), 8_(485-496).
3) Note that the member occurrence 5-123 is captured in the hopping path, therefore this hopping path does not have zero occurrences for the target member—it has one occurrence. That is not desirable. There are three solutions to resolve this limitation:
   a. Move to a next member of interest, since there are 100 member candidates for class 9.
   b. It is theoretically possible that none of the 100 member candidates can produce a hopping path with zero occurrences. In that case, the solution is to decrease the hopping granularity by adding more pairs to hop in-between. For example, 16 pairs can be used instead of 8. With more pairs, a better distribution of member occurrences among the considered pairs is made, with smaller intervals. For example, the theoretical interval between the occurrence of a member of interest for the number of pairs considered in the hopping path is, for ideal nominal distribution, when four pairs is considered is 496 over 4, or 124. For 8 pairs this interval drops to 62. For 16 pairs, this theoretical interval drops to 31. And so on.
      i. The disadvantage of considering more pairs to overcome the above described undesired situation is that more data is required in order to produce the same compression. The amount of data required is important, because this may limit what type of application the compression can be applied for. For example, an 8 million bits data requirement when a high definition movie is compressed is no issue, but it may be an issue when the target application will compress live streaming hi-fi audio.
   c. Keep the same number of pairs to create the hopping path with the zero occurrence member, such as keep the same number of 8 pairs, but choose different 8 pairs from the 496 possible pairs. This is again a computational task for the implementation, where the implementation has to “find” such 8 operational pairs out of the 496 possible pairs that will have such a hopping path to create a zero occurrence member.

On the same principle, a different hopping path, called second hopping path, can be created. Such a second hoping path can be used to create the equivalent of a maximum occurrence member.

In Scheme 4 implemented for Scheme 1, for a duplet case, the two members of interest, the first member with zero occurrences and the second member with a large number of occurrences, can be in two different pairs. For the first member, a first hopping path is created. For the second member, a “natural” pair may be used that has a large number of occurrences for a member of interest, but having such a pair is a matter of content and distribution within the respective IFDS slice. A second hopping path is introduced according to this disclosure, to reliably create, for a much wider range of content and distributions of an IFDS slice, a large number of occurrences for a member of interest. Similar to the first hopping path, the second hopping path uses a number of regular pairs to hop in-between.

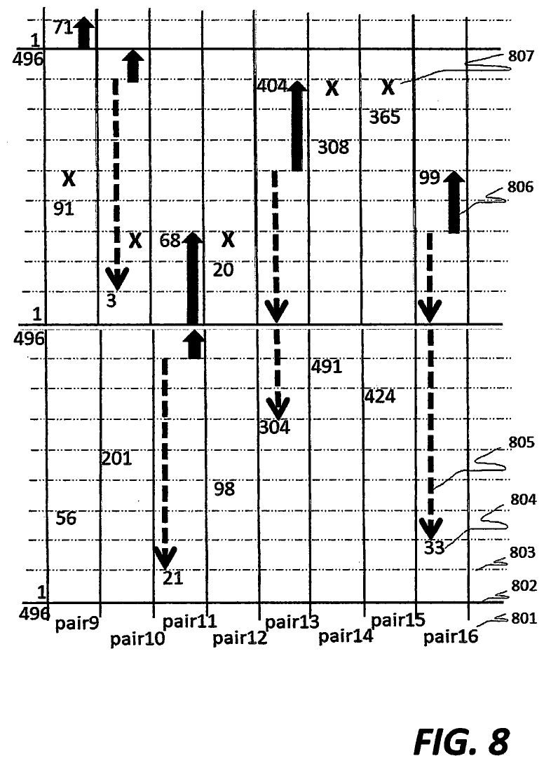

To detail the second hopping path, reference is made to FIG. 8. To eliminate any confusion with the first hopping path, the eight operational pairs considered for the second path will be called pair 9 to pair 16 (for the first hopping path, the eight pairs were called pair 1 to pair 8). Two 496 pairing range groups will be considered, with the following occurrences of a class 9 member of interest: 9-56, 10-201, 11-21, 12-98, 13-304, 14-491, 15-424, 16-33, 9-91, 10-3, 11-68, 12-20, 13-404, 14-308, 15-365, 16-99, 9-71.

The second hoping path is formed as follows:
a. Similarly to the first hopping path, if the group of 496 pairing ranges is the first in the IFDS, the second hopping path starts also with the first pair, called pair 9 now. Therefore,
   a. This said second hopping path starts with pair 9, and continues until the first occurrence of the member of interest in pair 9, creating the first leg of the second hopping path, respectively 9_(1-56).
   b. Then, the general rule is that it looks in the previous 496 group of pairing ranges and finds the pair that has an occurrence of the member of interest in the current group of pairing ranges with the highest probability. That is, since the probability of a class 9 member occurrence is one every 496 pairing ranges, that it finds the pair that has the largest number of non-member of interest occurrences to the current location, or in other words it searches for the occurrence of the member of interest, in any of the eight pairs, that is the farthest from the current location. That will be the pair with the highest probability to have another occurrence of the member of interest.
   c. For the case when the group of 496 pairing ranges is the first in the IFDS, the hopping path simply moves to the pair that did not have in the pairing ranges up to the current pairing range occurrence of the member of interest. For example, the current pairing range now is 56. Pair 11 with an occurrence of the member of interest at pairing range 21, and pair 16 with occurrence of the member of interest at pairing range 33 are eliminated, because the probability of having another occurrence at pairing range 56 for those pairs is lowest. Pairs 10, 12, 13, 14, and 15 have equal probability in this case, therefore pair 10 is taken since it is the first in the numerical order among the equals in probability.
   d. The said second hopping path therefore continues in pair 10, until the occurrence of the member of interest in this path, which occurs at pairing range 201, therefore creating the second leg of the second hopping path as 10_(57-201).
   e. Similarly, since the current pairing range is 201, pairs 9, 10, 11, 12, 16 are eliminated for the same reasoning as explained above, and pairs 13, 14, 15 are equal. The data structure continues on pair 13 (the first of the equals), therefore the third leg of the second hopping path is created as 13_(202-304).
   f. Next, since the current pairing range is 304, pairs 9, 10, 11, 12, 13, 16 are eliminated, and pairs 14, 15 are equal. The second hopping path continues on pair 14 (the first of the equals), therefore creating the fourth leg as 14_(305-491).
   g. For the last leg of the second hopping path, it looks in the second group of 496 pairing ranges at the general rule mentioned at a.b. above, and it finds that for the current pairing range 491, pair 11 meets the rule condition the best. Therefore, the last leg is 11_(492-496) plus 11_(1-68).
   h. Therefore, this second hopping path for the first group of 496 pairing ranges is 9_(1-56), 10_(57-201), 13_(202-304), 14_(305-491), 11_(492-496) plus 11_(1-68) in the second group of 496 pairing ranges.
b. For the second group of 496 pairing ranges, the second hopping path continues based on the general rule described above at a.b. The second hopping path is exemplified next, with reference to FIG. 8. For clarity, the meaning of the notations in FIG. 8 is:
   a. 801 is pointing to the row describing the names of the eight pairs: pair 9, pair 10, pair 11, pair 12, pair 13, pair 14, pair 15, pair 16.
   b. 802 is pointing to the solid horizontal lines with the meaning that this line is describing the border between consecutive groups of 496 pairing ranges. This line has on the lower side location 496 as the last location of the previous group, and on the upper side location 1 as the first location in the current group.
   c. 803 is pointing to the horizontal dotted lines where the number on the lower side of the dotted line shows the pairing range of the occurrence of the member of interest for which the second hopping path is built.
   d. 804 points to the numbers meaning the pairing range of the occurrence of the member of interest for which the second hopping path is built.
   e. 805 points to the dotted arrows showing that at that point and with respect to the pairing range from where the arrow starts, a decision is taken in which pair and with respect to which member (indicated by where the arrow ends), the second hopping path continues, all based on the general rule introduced above at a.b.
   f. 806 points to the solid arrows which depict the path of the second hopping path.
   g. 807 points to the “x” sign, symbolizing that those pairs are eliminated from continuing the second hopping path because they have the lowest probability of occurrence of the member of interest, among the other pairs.
c. All these are better understood with the explanations provided below in deriving the second hopping path in the second group of 496 pairing ranges. Therefore, the second hopping path continues as follows:
   a. As shown above, the last leg of the second hopping path through the previous group of 496 pairing ranges is through pair 11, and therefore continues into the current group of 496 pairing ranges into pair 11. Therefore, the second data structure continues into the current group of 496 pairing ranges with 11_(1-68), as shown above.
   b. Then, for the current pairing range 68, pairs 10 and 12 are eliminated because these pairs just had an occurrence of the member of interest, therefore the probability of having another member in the same pair is the lowest. Pair 11 is also eliminated for the same reasoning (location 68 is in pair 11, therefore having another occurrence in pair 11 has the lowest probability). For the remaining pairs, respective pair 9, 13, 14, 15, and 16, by applying the general rule mentioned above at a.b., pair 16 is optimal because the last occurrence of the member of interest is the farthest from the current pairing range 68. Therefore, the second hopping path continues with 16_(69-99).
   c. Same reasoning as detailed above for the derivations at pairing range 68 apply. Therefore, for the current pairing range 99, pairs 9, 10, 11, 12, and 16 are eliminated. From the remaining pairs, 13, 14, and 15, applying the general rule, pair 13 is optimal. Therefore, the said second hopping path continues as 13_(100-404).
   d. At pairing range 404, all the pairs are locked, i.e. they had an occurrence in the current group of 496 pairing ranges, therefore the second hopping path continues into the pair that had the farthest occurrence from pairing range 404, because that pair has the highest probability of having another occurrence for the member of interest. In this case, that pair is pair 10. Therefore, the second hopping path continues with 10_(405-496).
   e. Since in the third group of 496 pairing ranges, the only occurrence for the member of interest is 9-71, the second hopping path continues with 9_(1_71). This situation is an exception, and it applies only when in the last group there is only one occurrence for the member of interest. If in the third group there was no occurrence for the member of interest, then the said second hopping path would have continued with pair 10 until the last existing pairing range in the third group. Say this pairing range was also 71, then the second hoping path would be 10_(405-496) plus 10_(1-71).
   f. Therefore, the second hoping path, for the above given input data, is 11_(1-68), 16_(69-99), 13_(100-404), 10_(405-496) plus 9_(1-71).
d. The full second hopping path over all three groups of 496 pairing ranges, is being derived as 9_(1-56), 10_(57-201), 13_(202-304), 14_(305-491), 11_(492-496), 11_(1-68), 16_(69-99), 13_(100-404), 10_(405-496) plus 9_(1-71), and it contains 9 occurrences of the member of interest. For a nominal content and distribution, the number of occurrences would be two (one occurrence for each of the two complete groups of 496 pairing ranges), and maybe for a favourable distribution within a pair it may reach six occurrences.

The second hopping path is a must for Scheme 4 applied for Scheme 1. It can be applied for Scheme 1 alone if the second hopping path is replacing the common said column where clearly the member with the largest number of occurrences is created and the natural distribution happens to create a zero occurrences member or two members with a low number of occurrences.

A second hopping path can be created for all members of a class-in this case, the hopping, as described above, is occurring when not just a specific member occurs but when any member of a class occurs. For such an extension of a second hopping path to be applied for the members of a full class, the second hopping path is directly applicable for Scheme 2. And clearly, with such an extension, is applicable for Scheme 4 for Scheme 2.

A second hopping path can be extended also to be applied for Scheme 3. In this case, the second hopping path is created for all RI of a number of same type bits greater than a minimum. For example, it is created, as related to the example discussed above for the first hopping path, for all RI of same type bits with a number of same type bits greater or equal than 13 bits, and therefore the hopping, as described above, is occurring when not just a specific RI of same type bits occurs, but when ant RI of same type bits with the number of same type bits greater than a minimum occurs.

It is immediately apparent that an appropriately targeting first hopping path and an appropriately targeting second hopping path can be used for Scheme 1, Scheme 2, Scheme 3, Scheme 4 for Scheme 1, Scheme 4 for Scheme 2, therefore for any Scheme. Accordingly, by using said first and second hopping paths instead of regular matrix columns, a much more efficient compression can be achieved for regular distributions in an IFDS slice. Of course, for special distributions, using regular columns is preferred because the disadvantage of using hopping paths is that it requires multiple columns, i.e. there is a limit for compressing small IFDS, or in other words using hopping paths the size of an IFDS that can be compressed is larger than the size of an IFDS that can be compressed using regular matrix columns.

There can be as many hopping paths within a set of operational pairs (such as within 8 considered pairs, there can be as much as 8 hopping paths), with the condition that no portion of a hopping path and no portion of another hopping path, within the same group of 496 pairing ranges, can be common. For example, if the leg 11_(10-68) belongs to a first hopping path, no portion of this leg, such as 11_(1-69) or 11_(56-60) is allowed to be part of another first or a second hopping path.

All other RI pairs that are not part of any hopping path, for the operational pairs, are written in the output file as is, in proper order, so that at decompression can be restored.

As a matter of terminology, as described for Scheme 4 for Scheme 1 for example, when a duplet is used, i.e. a first column with a first member of zero occurrences is used with a second column with a second member of a large number of occurrences, is called that said first column is matched with said second column. The said matching in this case works as follows:
At a first line, said first member occurs on said second column, while on said first column any member occurs. The first member on said second column is exchanged with said any member on said first column.
This is repeated for all other similar lines, such that the second column ends up having zero occurrences of said first member and a large number of occurrences of said second member. At the same time said first column ends up having all occurrences of said first member that were on said second column, but that is OK, because it is known, at decompression, that the first column was supposed to have zero occurrences of said first member, therefore, it is known that these occurrences are coming from said second column.
The compression is achieved by combining the unique sequence of bits of a first number of bits of the second member with the unique sequence of bits of same first number of bits of the first member on said second column, after said exchange between said first and second columns, as described above, and therefore obtaining a unique sequence of bits of a number of bits equal to said first number of bits minus one.

Same concept of matching is applied when two columns, first and second column, of a first respectively second member of minimal number of occurrences are so called matched with a third column, or path, of a third member of maximum number of occurrences.
At a first matrix line, the first member on the first column occurs. To the unique sequence of bits of the first member, a_0 suffix is attached. For example, if the first member was of class 9 RI pair with a nine bit unique sequence of bits, now it becomes of a 10 bit unique sequence of bits. Every occurrence of said first member will add one bit compression loss therefore. That is why it is desired to have the minimum number of occurrences for this first member, so that the compression loss, represented by this extra bit, is minimal. Now, the unique sequence of this first member with a_1 suffix (a logic 1 bit suffix added) is becoming uniquely available.
At a second line, a second member of a second nine bit unique sequence, occurs. The nine bit unique sequence of this second member is replaced by the ten bit unique sequence that was made available above (the unique nine bit sequence of the first member followed by the _1 suffix). Similarly, every occurrence of this second member produces a one bit compression loss, therefore, similarly, this second member is desired to have a minimal number of occurrences. Now, the nine bit unique sequence of the second member is becoming available, since it is not used.
This nine bit unique sequence of the second member, made available as described together with the third member of maximum occurrences, behave exactly as described above for the zero occurrence-maximum occurrence case, and produces a compression gain of one bit per every occurrence of said third member. This compression gain is reduced by the compression loss represented, as described above, by the occurrences of said first and second members. That is why having a column with zero occurrence member, or a first hoping path, is preferred to having two columns of low occurrence members.

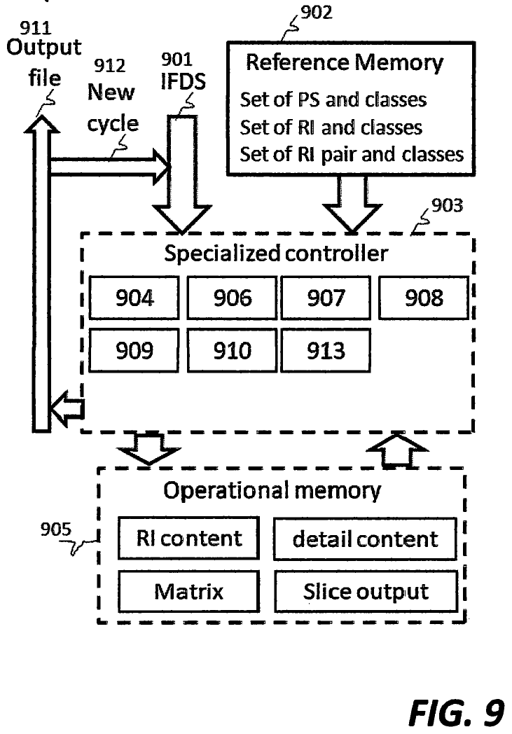

Highlights concerning the hardware implementation are discussed next, outlining the major blocks associated to the major operations. These discussions are provided to outline major possible components and implementation flow, and are by no means limiting for the present disclosure. A person skilled in the field easily can implement multiple obvious variations of the presented highlights. Highlights and discussions are provided referencing FIG. 9.
1 The set of processing strings (PS) is stored in a first memory partition. In a second memory partition, the set of root identifiers is stored. In a third memory partition, the set of RI pairs is stored. The first, the second, and the third partitions constitutes the reference memory, and this reference memory is fixed, i.e. it never changes for any IFDS. This is shown as 902 in FIG. 9.
2 In FIG. 9, 903 is a specialized controller, which can be implemented either as a fully custom hardware unit in order to provide optimal execution speed and performances for all specialized functionality, or as a more common processor where the required functionality is driven by software instructions. Either way, this functionality is described next without referring to one or the other implementation.
3 A first functionality of this specialized controller is to describe said IFDS in term of RI. This is implemented by block 904 in FIG. 9.
   a. The IFDS, 901 in FIG. 9, has a number of N bits, with the first bit being bit order 1 and the last bit being bit order N. The bits in IFDS are read sequentially by the specialized controller, from 1 to N. In the process of reading the bits, the specialized controller recognizes, by accessing the reference memory, a specific PS out of said set of PS. Said set of PS comprising of a number of PS classes, where within each PS class there are a number of unique PS of the same number of bits, with no two PS classes having PS of the same number of bits. The number of bits of said PS is in-between a minimum number and a maximum number. By using this set of PS, any IFDS can be described by partitioning said IFDS in consecutive PS which receives a sequential order number. This process has been fully described in said UPA.
   b. Every said PS corresponds to a unique RI out of said set of RI followed by a detail, with the number of bits of said RI plus the number of bits of said detail being equal to the number of bits of said PS. The RI receives a first sequential order number, in ascending order, from 1 to M, with 1 being the first RI (corresponding to the first PS) in said IFDS and M being the last RI (corresponding to the last PS) in said IFDS. The detail of each said RI receives the same first order number.
   c. Every such RI and detail are written in an operational memory, shown as 905 in FIG. 9, in two memory partitions labelled as RI content and detail content, where content refers to said IFDS content. At this point, said IFDS is fully described by said RI set, in accordance to said RI content which is processed further in order to provide compression.
4 A first decision is made by said specialized controller regarding what RI class, or what RI pair class is going to be used for compression. One of the considerations to make this decision is the application for which the compression is made for. For example if the application is a live audio stream or telephony, or broadcast, an RI class, such as class 4 or class 5 may be chosen, if the application is for storage of a large directory or movie, an RI pair class such as class 8, class 9, or even higher order classes, such as class 14, may be chosen.
5 A second decision is made by said specialized controller to partition said IFDS in consecutive slices, with each slice receiving a second order number between 1 and K, with 1 being for the first slice and K being the last slice. The block implementing the partition of IFDS in slices is block 906 in FIG. 9. For each slice, a corresponding RI content and detail content from the two partitions of said operational memory will correspond, content called slice content, slice content which will be tracked by said first order number.
6 For each slice, a compression matrix is created. Function of the content and distribution of the elements inside this matrix, a compression technique among several compression techniques is chosen. The creation of this compression matrix for each slice is implemented by block 907 in FIG. 9. Each of the K slices are compressed independently from one another.
   a. Function of the decision made above to compress using RI or RI pair, generically called binary constructs, said RI content of a slice is partitioned in groups of RI called pairing ranges. A pairing range contains a second number of RI that is decided as a function of what class that RI or RI pair that was decided to compress with, belongs to. For example, for an RI class 4, said second number of RI in said pairing range is 16, while for an RI pair class 9, said second number of RI in said pairing range is 32.
   b. Once a pairing range is decided, since each slice has a first number of RI and each pairing range has a second number of RI, each slice will have a third number of pairing ranges. This third number is the number of lines in said slice matrix, with the number of columns being equal to said second number of RI when the decision is made to compress using RI, or being equal to combinations of said second number taken 2 when the decision is made to compress using RI pair.
   c. This matrix, for each slice, is written in the 905 operational memory of FIG. 9 as a partition called “Matrix”.
7 As a function of said content of said slice as reflected in said matrix of that slice, a sad Scheme out of Scheme 1, 2, 3, or 4, is decided by said specialized controller for compression. The specialized controller, if it cannot find a regular column in said matrix to compress according to the chosen scheme, or if the compression achieved with said regular column is not larger than a set target value, will create a hopping path, first or second or both, as a function of the chosen scheme. All these are implemented by block 908 in FIG. 9.
8 A compressed output file for every slice is generated and written in said operational memory, shown in FIG. 9 at 905 as “Slice output”. This is implemented by block 909 shown in FIG. 9.
9 Once the compression of all slices is completed, the compressed output files for every slice are assembled according to the second order number, generating an output file representing the full compressed IFDS, and is called that a compression cycle is completed. This is implemented by block 910 shown in FIG. 9.
10 The output file is sent out, for use by the intended application, as shown in FIG. 9 by 911. If, for example, the output file is larger than a target size, the output file is not submitted to the intended application and is instead fed back to the input of the compression process, as a new IFDS, for a new compression cycle. Such compression cycles can be repeated in a loop until a compression target performance, such as a target size for the output file is met. Feeding the output file for a new compression cycle, in this compression loop, is shown in FIG. 9 by 912. The entire process of testing the output file for the target compression performance, and feeding back the output file for a new compression cycle is implemented by block 913 as shown in FIG. 9.
11 Decompression, i.e. obtaining the initial IFDS from said output file, is executed using reverse, dual functionality blocks on an exact, reverse flow. Same reference memory, with same content is required. Same operational memory to write similar data during decompression is required. The specialized controller has blocks of dual, reverse functionality as compared to compression.

From reading the present disclosure, other variations and modifications will be apparent to the skilled person. Such variations and modifications may involve equivalent and other features which are already known in the art or are implied by the embodiments presented in this disclosure. Such variations and modifications may increase the performance of the BDCD method, such as may increase the compression/decompression efficiency or speed.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination. The applicant hereby gives notice that new claims may be formulated to such features and/or combinations of such features during the prosecution of the present application or of any further application derived therefrom.

For the sake of completeness it is also stated that the term “comprising” does not exclude other elements or steps, the term “a” or “an” does not exclude a plurality, and reference signs in the claims shall not be construed as limiting the scope of the claims.

1. A digital system designed to compress any arbitrary binary input data string (IFDS) of a first size in term of number of bits that is larger than a minimum size, implemented in hardware using hardware blocks of specialized functionality that are self-contained within said digital system, with said implementation being integrated in a hardware device of broad functionality application that requires binary compression, comprising:
a first said hardware block as a first data storage device known as reference memory, comprising:
a first number of storage locations, with each said storage location being of a second number of bits of standard allocation content that never changes;
said first number is divided between a third number of partitions, with each said partition having a fourth number of said storage locations with said fourth number of one partition not being equal to said fourth number of another partition;
said third number of partitions comprising:
a first partition of a fifth number of said storage locations, storing a set of processing strings (PS), wherein:
each of said PS is unique, comprising a number of bits of a unique sequence;
said set of PS is organized in a number of PS classes comprising a finite number of said PS with no two said PS classes having said PS of a same number of bits;
each PS comprising a unique root identifier (RI) followed by a detail, with the number of bits of said RI plus the number of bits of said detail being equal to said number of bits of said PS;
a second partition of a sixth number of said storage locations, storing a set of said root identifiers (RI), wherein;
each of said RI is unique, comprising a number of bits of a unique sequence;
a number of said RI is developed for each of said PS class;
said set of RI comprising all said RI of all said PS, and is organized in a number of RI classes comprising a finite number of said RI with no two said RI classes having said RI of a same number of bits;
a third partition of a seventh number of said storage locations, storing a set of said RI pairs, wherein:
every said RI pair is formed by putting together two said RI, with each of said RI pair comprising a number of bits of a unique sequence;
said set of RI pairs is organized in a number of RI pair classes comprising a finite number of said RI pairs with no two said RI pair classes having said RI pairs of same number of bits;
with RI, RI pair, aggregately being called binary constructs, said RI classes, RI pair classes, aggregately being called classes, and said set of RI, set of RI pair, aggregately being called sets;
a second said hardware block known as a specialized controller of specialized functionality, comprising:
a first said specialized functionality of fully and uniquely partitioning said IFDS in term of said PS by accessing said first partition and recognizing a said PS in said IFDS, and such creating a series of consecutive PS that occur in said IFDS, with every said consecutive PS receiving a first order number starting with one for a first PS in said IFDS, with said first order number being in ascending order;
a second said specialized functionality of associating every said consecutive PS such said recognized in said IFDS to a corresponding said RI of said second partition, and separating a corresponding said detail, and such creating a first database with said association representing said IFDS content in term of said RI, said detail, with each said association preserving said first order number, and such uniquely describing said IFDS using said set of RI;
a third said specialized functionality of creating out of said first database groups of consecutive of said RI, with such a said group known as pairing range, with said pairing range having an eighth number of said consecutive content RI;
a fourth said specialized functionality of partitioning said IFDS in a number of consecutive slices, with each said slice being assigned a second order number starting with one for a first slice in said IFDS, with said second order number being in ascending order, and with each slice having a ninth number of said pairing ranges;
a fifth said specialized functionality of creating a matrix for each of said slices, wherein every line of said matrix consists of either said eighth number of RI, in the order as found in said pairing range, or of RI pairs, in the order as determined by combinations of said eighth number taken two with said combinations being in the order of said RI as found in said pairing range, and wherein the columns of said matrix are formed by stacking said ninth number of lines formed by each of said pairing ranges, with each column having therefore a said ninth number of locations;
a third said hardware block as a second data storage device known as operational memory that is written by said specialized controller, comprising said first database and said matrix for every said slice;
a sixth said specialized functionality of generating a compressed output file for each of said slice, comprising:
analyzing each column in said matrix in term of number of occurrences of each said binary construct of each said class occurring in said column, tabulating said occurrences, and saving said tabulated occurrences together with said associated detail to said occurrences in a third partition of said second data storage device;
employing a first technique comprising:
comparing said binary constructs of one or more of said classes in one or more said columns of said matrix of said slice in term of said occurrences, in term of said number of bits, and in term of said class;
selecting one or more said binary constructs based on one or more predefined comparison results;
processing said selected binary constructs to generate compression gain;
writing a compressed output file for each of said slice by writing said columns of said selected and processed binary constructs together with associated detail, called selected columns, and all said binary constructs and associated detail that are not within said selected columns of all of said pairing ranges;
a seventh said specialized functionality of assembling said compressed output files of every said slice, with said assembling being made in accordance to said second order number, generating a global compressed output file for said IFDS of a second size with compression gain being achieved if said second size is smaller than said first size, and such completing a compression cycle;
repeating said compression cycle a number of times until a compression target is achieved, wherein said repeating a compression cycle comprising said global compressed output file of current said compression cycle becoming a new said IFDS for the next said compression cycle.

2. Said digital system of claim 1 wherein one or more of said hardware blocks are not said self-contained within said digital system, comprising:
said first hardware block is allocated within a data storage device of said hardware system;
said third hardware block is allocated within a data storage device of said hardware system;
said second hardware block with its said specialized functionality is fully or partly taken over by a hardware processor of broad functionality within said hardware system, that can perform said specialized functionality by following a series of software instructions.

3. A first said first technique of claim 1, comprising:
determining, for each of said columns of said matrix, either a first said binary construct of a first said class, with no occurrences in said column, or a second and a third said binary construct of same said first class that have the smallest number of occurrence in said column;
determining, for each of said columns of said matrix, a fourth said binary construct of same first class, with maximum number of occurrences in said column;
matching a first column with a said first binary construct with a third column with a said fourth binary construct, or a second column with a said second and third binary construct with a third column with a said fourth binary construct, wherein said first column and said third column may be the same column, or said second column and said third column may be the same column, with said first column, second column and third column, when said first and third column and said second and third column are not the same, not having any common said binary constructs of said pairing ranges;
defining either a first choice comprising a first and a fourth said binary constructs as said selected binary constructs, or a second choice comprising a second, a third, and a fourth said binary constructs as said selected binary constructs, and choosing a said first choice or a said second choice that provides the largest compression gain, comprising:
for said first choice, said processing comprising said number of bits of said fourth binary construct being altered by said first binary construct such that the compression gain per each occurrence of said fourth binary construct is one;
for said second choice, said processing comprising said number of bits of said fourth binary construct being altered by said second and third binary constructs such that the compression gain per each occurrence of said fourth binary construct is one, with one bit being written in said output file per each occurrence of said second and third binary constructs;
for both said first and second choice, a number of bits is written in said output file to identify said first and third columns, and said first and fourth binary constructs, respectively said second and third columns and said second, third, and fourth binary constructs.

4. A second said first technique of claim 1, comprising:
determining, for each of said columns of said matrix, either a first said binary construct of a first said class, with no occurrences in said column, or a second said binary construct of a second said class that is the same or different than said first class, that have the smallest number of occurrence in said column;
determining, for each of said columns of said matrix, a third said class that is different than said first and said second class, with said binary constructs of said third class having a number of bits that is larger than said number of bits of said first or said second class, wherein the number of occurrences of all said binary constructs of said third class is the largest than all other classes in said column;
matching a first column with a said first binary construct with a third column with a said third class, or a second column with a said second binary construct with a third column with a said third class, wherein said first column and said third column may be the same column, or said second column and said third column may be the same column, with said first column, second column and third column, when said first and third column and said second and third column are not the same, not having any common said binary constructs of said pairing ranges;
defining either a first choice comprising a first said binary construct and a third said class as said selected binary constructs, or a second choice comprising a second said binary construct and a third said class as said selected binary constructs, and choosing either a said first choice or a said second choice that provides the largest compression gain, comprising:
for said first choice, said processing comprising creating a unique alternate representation for each of one or more of said binary constructs of said third class by concatenating said unique number of bits of said first binary construct with a suffix comprising a number of bits smaller or equal to said number of bits of said third class minus said number of bits of said first binary construct, such that a said compression gain of one or more is achieved for every occurrence of said one or more of said binary constructs of said third class;
for said second choice, said processing comprising creating a unique alternate representation for each of one or more of said binary constructs of said third class by concatenating said unique number of bits of said second binary construct with a suffix comprising a number of bits smaller or equal to said number of bits of said third class minus said number of bits of said second binary construct, such that a said compression gain of one or more is achieved for every occurrence of said one or more of said binary constructs of said third class, with one bit being written in said output file per each occurrence of said second binary construct;
for both said first and second choice, a number of bits is written in said output file to identify said first column, said third column, said first binary construct and said third class respectively said second column, said third column, said second binary construct and said third class.

5. A third said first technique of claim 1, comprising:
locating, within each of said columns of said matrix, a said RI of a number of same type bits as either logic 0 or logic 1 that is larger than a first minimum number, called located RI;
reserving a said RI of a number of bits smaller than said first minimum number, wherein said reserved RI cannot be used to said describe said IFDS and instead is used to transform all said located RI by developing a unique alternate representation for each of said unique located RI comprising concatenating said unique bits of said reserved RI with a unique suffix comprising a variable number of bits of a sequence of bits, such that the number of bits of said reserved RI plus said variable number of bits of said suffix is smaller or equal to the number of bits of said located RI, and wherein the difference between said number of bits of said located RI and said number of bits of said reserved RI with said concatenated suffix is said compression gain per each occurrence of said located RI and said suffix is chosen to maximize said compression gain and said describe all said located RI that can occur in said IFDS;
when a said reserved RI, associated to a said PS, is not occurring in said column of a located RI, said processing defines a first choice of compressing said column called a direct column, with said selectable RI being said located RI and said reserved RI with said suffix, comprising replacing said located RI by said reserved RI with said suffix to generate a compression gain equal to said difference between said number of bits of said located RI and said number of bits of said reserved RI with said suffix per each occurrence of said located RI;
when a said reserved RI, associated to a said PS, is occurring in said column of a located RI, said processing defines a second choice of compressing said column called an indirect column by matching a second column in which said reserved RI and a said located RI does not occur with said column of a located RI, with said selectable RI being said located RI and said reserved RI with said suffix, wherein by replacing said located RI by said reserved RI with said suffix, a compression gain equal to said difference between said number of bits of said located RI and said number of bits of said reserved RI with said suffix is generated per each occurrence of said located RI, and wherein said indirect column and said second column not having any common said binary constructs of said pairing ranges;
for both said first and second choice, a number of bits is written in said output file to identify said direct column, respectively said indirect column and said second column.

6. A fourth said first technique of claim 1, comprising:
determining, for each of said columns of said matrix, a first said binary construct of a first class, with maximum number of occurrences in said column;
choosing a first said column of a said first binary construct that has the maximum number of occurrences among all said columns of said first binary constructs;
combining multiple columns of said matrix into a path known as first hopping path characterized by having a second said binary construct of same said first class with no occurrences in said path and wherein said multiple columns do not include said first column, with said path comprising:
determining, for each said matrix line, said column where said second binary construct occurs;
when said second binary construct does not occur on any column of a current line, then said path continues on next line on same column as it was on current line;
when said second binary construct occurs on one or more columns of said current line, then said path continues on next line on the first column in mathematical order of said one or more columns on which said second binary construct occurs on said current line;
when said second binary construct occurs on the same column of said current line where said path is, then said path for said second binary construct is invalid and a new path for another said second binary construct within same said class is created;
matching said path with said second binary construct with a said first column with said first binary construct, wherein said first column and said path may be the same when said first binary construct has a larger number of occurrences across said path than said first binary construct has on said first column, with said first column and said path, when said first column and said path are not the same, not having any common said binary constructs of said pairing ranges;
said first binary construct and said second binary construct are said selected binary constructs, providing said compression gain, comprising:
said processing comprising said number of bits of said first binary construct being altered by said second binary construct such that the compression gain per each occurrence of said first binary construct is one;
a number of bits is written in said output file to identify said first column, said first path, and said first and second binary constructs.

7. A fifth said first technique of claim 1, comprising:
determining, for each of said columns of said matrix, a first said class, with said binary constructs of said first class having a first number of bits, wherein the number of occurrences of all said binary constructs of said first class is the largest than all other classes in said column;
choosing a first column of a said first class that has the maximum number of occurrences for said binary constructs in said first class than all other said columns have;
combining multiple columns of said matrix into a path known as first hopping path characterized by having a first said binary construct of a number of bits smaller than said first number of bits of said binary constructs of said first class with no occurrences of said first binary construct in said path, and wherein said multiple columns do not include said first column, with said path comprising:
determining, for each said matrix line, said column where said first binary construct occurs;
when said first binary construct does not occur on any column of a current line, then said path continues on next line on same column as it was on current line;
when said first binary construct occurs on one or more columns of said current line, then said path continues on next line on the first column in mathematical order of said one or more columns on which said first binary construct occurs on said current line;
when said first binary construct occurs on the same column of said current line where said path is, then said path for said first binary construct is invalid and a new path for another said first binary construct within same said class is created;
matching a said first column of a said first class with a said first binary construct of a said path, wherein said first column and said path is the same when a said first class has a larger number of occurrences of all said binary constructs of said first class in said path than it has in said first column, with said first column and said path, when said first column and said path are not the same, not having any common said binary constructs of said pairing ranges;
said first binary construct and said first class are said selected binary constructs, providing said compression gain, comprising:
said processing comprising creating a unique alternate representation for each of one or more of said binary constructs of said first class by concatenating said unique number of bits of said first binary construct with a suffix comprising a number of bits smaller or equal to said number of bits of said first class minus said number of bits of said first binary construct, such that a said compression gain of one or more is achieved for every occurrence of said one or more of said binary constructs of said first class;
a number of bits is written in said output file to identify said first column, said path, said first binary construct and said first class.

8. A sixth said first technique of claim 1, comprising:
locating, within each of said columns of said matrix, all said RI of a number of same type bits as either logic 0 or logic 1 that is larger than a minimum number of bits, called located RI;
choosing among said located RI a first located RI that has the maximum number of same type bits among all said located RI, with said chosen located RI being on a first said column;
combining multiple columns of said matrix, excluding said first column, into a path known as first hopping path characterized by having a first said binary construct of a first number of bits with no occurrences in said path, comprising:
determining, for each said line, said column where said second binary construct occurs;
when said second binary construct does not occur on any column of a current line, then said path continues on next line on same column as it was on current line;
when said second binary construct occurs on one or more columns of said current line, then said path continues on next line on the first column in mathematical order of said one or more columns on which said second binary construct occurs on said current line;
when said second binary construct occurs on the same column of said current line where said path is, then said path for said second binary construct is invalid and a new path for another said second binary construct within same said class is created;
said first number of bits of said first binary construct is the smallest for which a said path can be created, and is smaller than said minimum number of bits;
matching said path with said first binary construct with said first column with said chosen located RI, wherein said first column and said path is the same when said chosen located RI is captured in said path, with said first column and said path, when said first column and said path are not the same, not having any common said binary constructs of said pairing ranges;
said first binary construct and said chosen located RI are said selected binary constructs, providing said compression gain, comprising:
said processing comprising:
developing a unique alternate representation for said chosen located RI comprising concatenating said unique bits of said unique binary construct with a unique suffix comprising a variable number of bits of a sequence of bits, such that the number of bits of said first binary construct plus said variable number of bits of said suffix is smaller or equal to the number of bits of said chosen located RI, and wherein the difference between said number of bits of said chosen located RI and said number of bits of said first binary construct with said concatenated suffix is said compression gain per each occurrence of said chosen located RI, and when said suffix is chosen to maximize said compression gain and said describe all said located RI that can occur in said IFDS;
replacing said chosen located RI by said first binary construct with said suffix to generate said compression gain equal to said difference between said number of bits of said chosen located RI and said number of bits of said first binary construct with said suffix, per each occurrence of said chosen located RI;
a number of bits is written in said output file to identify said first column, said path, said first binary construct, said chosen located RI.

9. A seventh said first technique of claim 1, comprising:
locating, within each of said columns of said matrix, all said RI of a number of same type bits as either logic 0 or logic 1 that is larger than a minimum number of bits, called located RI;
combining multiple columns of said matrix with each said column having one or more of said located RI, in a second path known as second hopping path characterized by having a maximum number of located RI, comprising:
when said second path is on a first column of a first line of said matrix, said second path continues on said first column until on said first column at a second line a said located RI occurs;
once said second path is at said second line on said first column, it is determined how many lines from said second line a said located RI occurred on any of the other columns besides said first column, and said column with the largest said number of lines is selected to continue said second path on;
when there are more than one such columns that have an equal said largest number of lines, said second path continues on said column that is the first in mathematical order;
combining multiple columns of said matrix into a first path known as first hopping path characterized by having a first said binary construct of a first number of bits with no occurrences in said first path, comprising:
said first path and said second path cannot have any common said binary constructs;
determining, for each said line, said column where said first binary construct occurs;
when said first binary construct does not occur on any column of a current line, then said path continues on next line on same column as it was on current line;
when said first binary construct occurs on one or more columns of said current line, then said path continues on next line on the first column in mathematical order of said one or more columns on which said first binary construct occurs on said current line;
when said first binary construct occurs on the same column of said current line where said path is, then said path for said first binary construct is invalid and a new path for another said first binary construct within same said class is created;
said first number of bits of said first binary construct is the smallest for which a said path can be created, and is smaller than said minimum number of bits;
matching a said first path of a said first binary construct with a said second path of said located RI, with said first path and said second path not having any common said binary constructs of said pairing ranges;
said first binary construct and said located RI are said selected binary constructs, providing said compression gain, comprising:
said processing comprising:
developing a unique alternate representation for each said located RI comprising concatenating said unique bits of said first binary construct with a unique suffix comprising a variable number of bits of a sequence of bits, such that the number of bits of said first binary construct plus said variable number of bits of said suffix is smaller or equal to the number of bits of said located RI, and wherein the difference between said number of bits of said located RI and said number of bits of said first binary construct with said concatenated suffix is said compression gain per each occurrence of said located RI, and when said suffix is chosen to maximize said compression gain and said describe all said located RI that can occur in said IFDS;
replacing said located RI by said first binary construct with said suffix to generate a compression gain equal to said difference between said number of bits of said located RI and said number of bits of said first binary construct with said suffix, for every said occurrence of said located RI;
a number of bits is written in said output file to identify said first path, said second path, said first binary construct.

10. An eighth said first technique of claim 1, comprising:
determining, for each of said columns of said matrix, a first said binary construct of a first class, called located binary construct;
combining multiple columns of said matrix with each said column having one or more of said located binary constructs, in a second path known as second hopping path characterized by having a maximum number of said located binary constructs, comprising:
when said second path is on a first column of a first line of said matrix, said second path continues on said first column until on said first column of a second line a said located binary construct occurs;
once said second path is on said second line on said first column, it is determined how many lines from said second line a said located binary construct occurred on any of the other columns besides said first column, and said column with the largest said number of lines is selected to continue said second path on;
when there are more than one such columns that have an equal said largest number of lines, said second path continues on said column that is the first in mathematical order;
combining multiple columns of said matrix into a first path known as first hopping path characterized by having a second said binary construct of same said first class with no occurrences in said first path, with said first path comprising:
said first path and said second path cannot have any common said binary constructs;
determining for each said line, said column where said second binary construct occurs;
when said second binary construct does not occur on any column of a current line, then said first path continues on next line on same column as it was on current line;
when said second binary construct occurs on one or more columns of said current line, then said first path continues on next line on the first column in mathematical order of said one or more columns on which said second binary construct occurs on said current line;
when said second binary construct occurs on the same column of said current line where said first path is, then said first path for said second binary construct is invalid and a new first path for another said second binary construct within same said class is created;
matching a said first path of a said second binary construct with a said second path of said located binary constructs, with said first path and said second path not having any common said binary constructs of said pairing ranges;
said first binary construct and said second binary construct are said selected binary constructs, providing said compression gain, comprising:
said processing comprising said number of bits of said located binary construct being altered by said second binary construct such that the compression gain per each occurrence of said located binary construct is one;
a number of bits is written in said output file to identify said first path, said second path, said located binary construct and second binary construct.

11. A ninth said first technique of claim 1, comprising:
combining multiple columns of said matrix with each said column having one or more binary constructs of a first class of a first number of bits, in a second path known as second hopping path characterized by having a maximum number of said binary constructs of said first class, comprising:
when said second path is on a first column at a first line of said matrix, said second path continues on said first column until on said first column at a second line a said binary construct of said first class occurs;
once said second path is at said second line on said first column, it is determined how many lines from said second line a said binary construct of said first class occurred on any of the other columns besides said first column, and said column with the largest said number of lines is selected to continue said second path on;
when there are more than one such columns that have an equal said largest number of lines, said second path continues on said column that is the first in mathematical order;
combining multiple columns of said matrix into a first path known as first hopping path characterized by having a first said binary construct of a number of bits smaller than said binary constructs of said first class with no occurrences in said first path, with said first path comprising:
said first path and said second path cannot have any common said binary constructs;
determining for each said line, said column where said first binary construct occurs;
when said first binary construct does not occur on any column of a current line, then said first path continues on next line on same column as it was on current line;
when said first binary construct occurs on one or more columns of said current line, then said first path continues on next line on the first column in mathematical order of said one or more columns on which said first binary construct occurs on said current line;
when said first binary construct occurs on the same column of said current line where said first path is, then said first path for said first binary construct is invalid and a new said first path for another said first binary construct within same said class is created;
matching a said first path of a said first binary construct with a said second path of said binary construct of said first class, with said first path and said second path not having any common said binary constructs of said pairing ranges;
said first binary construct and said first class are said selected binary constructs, providing said compression gain, comprising:
said processing comprising creating a unique alternate representation for each of said binary constructs of said first class by concatenating said unique number of bits of said first binary construct with a suffix comprising a number of bits smaller or equal to said number of bits of said first class minus said number of bits of said first binary construct, such that a said compression gain of one or more is achieved for every occurrence of every occurring said binary constructs of said first class;
a number of bits is written in said output file to identify said first path, said second path, said first binary construct and said first class.

12. Said matching of a first column with a said first binary construct with no occurrences on said first column with a third column with a said fourth binary construct with maximum number of occurrences on said third column, of claim 3, comprising:
at a first said matrix line, where on said third column a said first binary construct occurs, and where on said first column any arbitrary binary construct occurs, an exchange between said third column and said first column occurs;
after all such said exchanges, on all said matrix lines, said third column has no occurrences of said first binary construct and a maximum number of occurrences of said fourth binary construct, while said first column has a number of occurrences of said first binary construct that were occurring on said third column;
at a second said matrix line where said fourth binary construct occurs, said unique sequence of bits of a first number of bits of said fourth binary construct combined with said unique sequence of bits of a first number of bits of said first binary construct, lead to a unique sequence of bits for said fourth binary construct of a number of bits equal to said first number of bits minus one.

13. Said matching of a second column with a said second and third binary construct with smallest number of occurrences on said second column with a third column with a said fourth binary construct with maximum number of occurrences on said third column, of claim 3, comprising:
at a first said matrix line, where on said second column a said second binary construct occurs, said second binary construct is modified by adding to said unique sequence of bits of said second binary construct a suffix comprising of a zero logic bit;
at a second said matrix line, where on said second column a said third binary construct occurs, said third binary construct is replaced by said unique sequence of bits of said second binary construct with an added suffix comprising of a logic one bit, and such releasing said unique sequence of bits of said third binary construct;
at a third said matrix line, where on said third column a said third binary construct occurs, and where on said second column any arbitrary binary construct occurs, an exchange between said third column and said second column occurs;
after all such said exchanges, on all said matrix lines, said third column has no occurrences of said third binary construct and a maximum number of occurrences of said fourth binary construct, while said second column has a number of occurrences of said third binary construct that were occurring on said third column;
at a fourth said matrix line where said fourth binary construct occurs, said unique sequence of bits of a first number of bits of said fourth binary construct combined with said unique sequence of bits of a first number of bits of said third binary construct, lead to a unique sequence of bits for said fourth binary construct of a number of bits equal to said first number of bits minus one.

14. A method to compress, without any data loss, any arbitrary binary input data string (IFDS) of a first size in term of number of bits that is larger than a minimum size, comprising:
uniquely describing said IFDS using a set of binary constructs that is developed to describe any said IFDS, with said set comprising a number of classes wherein each said class has a number of unique said binary constructs of a number of bits of a unique sequence;
organizing said described IFDS in a consecutive sequence of said binary constructs as occurring in said IFDS, wherein each of said consecutive binary constructs is being assigned a first order number in an ascending value;
partitioning said organized and described IFDS in groups of said consecutive binary constructs called pairing ranges, with each such group having a first number of said consecutive binary constructs with each said binary construct having a position in an ascending order of a second order number, and with said pairing ranges being assigned a third order number in ascending value;
organizing said partitioned IFDS in a matrix, with a matrix line comprising said binary constructs of a said pairing range and a said matrix column comprising said binary constructs of a same position in said pairing ranges and in the second order number;
a first technique of locating a first said column of said matrix having a first said binary construct with no occurrences in said column;
a second technique of locating a second said column of said matrix having a second said binary construct with a large number of occurrences in said column;
a third technique of locating a third said column of said matrix having a third said binary construct of a number of same type bits that is larger than a minimum number;
a fourth technique of combining a first number of said columns of said matrix in order to create a first path called first hopping path, having a fourth said binary construct with no occurrences in said first path;
a fifth technique of combining a second number of said columns of said matrix in order to create a second path called second hopping path, having a fifth said binary construct with a large number of occurrences in said second path;
creating compression gain by employing one or more of:
matching said first column with said second column in order to create said compression gain for each occurrence of said second binary construct by using said first binary construct;
matching said first column with said third column in order to create said compression gain for each occurrence of said third binary construct by using said first binary construct;
matching said first path with said second column in order to create said compression gain for each occurrence of said second binary construct by using said fourth binary construct;
matching said first path with said third column in order to create said compression gain for each occurrence of said third binary construct by using said fourth binary construct;
matching said first path with said second path in order to create said compression gain for each occurrence of said fifth binary construct by using said fourth binary construct;
matching said first column with said second path in order to create said compression gain for each occurrence of said fifth binary construct by using said first binary construct;
wherein said first column, second column, third column, first path, second path share no binary constructs unless any two of said first column, second column, third column, first path, second path are identical;
wherein matching one column of one binary construct with zero occurrences in said one column with another column of another binary construct with large number of occurrences in said another column, comprising:
on every said line where said one binary construct occurs on said another column while on said one column there is any binary construct, said one binary construct is moved on said one column and said any binary construct is moved on said another column;
at every line where said another binary construct occurs on said another column, said unique sequence of bits of a first number of bits of said another binary construct combined with said unique sequence of bits of a first number of bits of said one binary construct, lead to a unique sequence of bits for said another binary construct of a number of bits equal to said first number of bits minus one;
writing a compressed output file by first writing said columns and paths employed to create said compression, and then writing all other binary constructs within said matrix, with said output file having a second size smaller than said first size;
reversing said compression by creating said IFDS from said compressed output file, i.e. decompressing said output file, comprising reverse, dual functionality steps.

15. A method to lossless compress any arbitrary binary input data string (IFDS) greater than a minimum size in term of number of bits, comprising:
describing said IFDS using a set of developed unique binary constructs with said set never changing with said IFDS and every said binary construct having a number of bits of a unique sequence, wherein every said binary constructs that occurs a number of times in said IFDS is tabulated to create a content of said IFDS;
partitioning said content in a number of groups of consecutive said binary constructs called pairing ranges;
organizing said content in a matrix, with the number of matrix lines equal to the number of said pairing ranges in said IFDS and the number of columns being proportional to the number of said binary constructs in a said pairing range;
developing relationships between said binary constructs of every said column, with said relationships comprising comparisons of said number of bits of said binary constructs called first relationship, of said number of occurrences of said binary constructs called second relationship, or both said number of bits and said number of occurrences of said binary constructs called third relationship;
developing relationships between said binary constructs of multiple said columns, with said relationships comprising comparisons of said number of bits of said binary constructs across multiple said columns called fourth relationship, of said number of occurrences of said binary constructs across multiple said columns called fifth relationship, or both said number of bits and said number of occurrences of said binary constructs across multiple said columns called sixth relationship;
combining multiple said columns to create a path across all lines, with said path having one said binary construct of each said line, wherein said path is created such that a specific said binary construct of a specific number of bits to have either zero occurrences across said path called first path, or to have maximum number of occurrences across said path called second path;
creating compression gain by matching and processing said binary constructs of two or more of said first path, second path, said first relationship, said second relationship, said third relationship, said fourth relationship, said fifth relationship, said sixth relationship; and
generating a compressed output of a second size smaller than said first size.
